(19) United States
(12) Patent Application Publication
(10) Pub. No.: US 2025/0259847 A1
(43) Pub. Date: Aug. 14, 2025

(54) Threshold Voltage Tuning Using Aluminum Layer as Dipole Material

(71) Applicant: Taiwan Semiconductor Manufacturing Company, Ltd., Hsin-Chu (TW)

(72) Inventors: Jia-Yun XU, Hsinchu City (TW); Pei Ying LAI, Hsinchu (TW); Tsung-Ta TANG, Hsinchu City (TW); Alvin Universe TANG; Cheng-Hao HOU, Hsinchu City (TW)

(21) Appl. No.: 18/438,875

(22) Filed: Feb. 12, 2024

(51) Int. Cl. H01L 21/28; H01L 21/3115; H01L 21/8234; H01L 27/12; H01L 29/40; H01L 29/423; H01L 29/49; H01L 29/51; H01L 29/775; H01L 29/78; H01L 29/786

(52) U.S. Cl. CPC H01L 21/28158; H01L 21/3115; H10D 30/6739; H10D 64/01; H10D 64/685; H10D 64/691; H10D 84/0144; H10D 84/038; H10D 87/00; H10D 30/43; H10D 30/62; H10D 30/6735; H10D 30/6757

(57) ABSTRACT

Dipole engineering techniques are disclosed herein that may be implemented when fabricating gate stacks, such as a gate stack of a transistor. An exemplary method for forming a gate stack of a transistor includes forming a high-k dielectric layer, forming a p-dipole dopant source layer over the high-k dielectric layer, performing a thermal drive-in process that drives aluminum from the p-dipole dopant source layer into the high-k dielectric layer, and after removing the p-dipole dopant source layer, forming at least one electrically conductive gate layer over the high-k dielectric layer. The p-dipole dopant source layer includes an aluminum layer. The p-dipole dopant source layer may further include an aluminum oxide layer and/or an aluminum nitride layer.

### BACKGROUND

The electronics industry has experienced an ever-increasing demand for smaller and faster electronic devices that are simultaneously able to support a greater number of increasingly complex and sophisticated functions. To meet these demands, there is a continuing trend in the integrated circuit (IC) industry to manufacture low-cost, high-performance, and low-power ICs. Thus far, these goals have been achieved in large part by reducing IC dimensions (for example, minimum IC feature size), thereby improving production efficiency and lowering associated costs. However, such scaling has also increased complexity of the IC manufacturing processes. Thus, realizing continued advances in IC devices and their performance requires similar advances in IC manufacturing processes and technology.

One area of advancement is directed to providing ICs with transistors having multiple threshold voltages (Vt), which can boost performance of some transistors of an IC while reducing power consumption of other transistors of the IC. However, providing multiple threshold voltages has been challenging for multigate devices, such as fin-like field effect transistors, gate-all-around transistors including nanowires and/or nanosheets, and other types of multigate devices, because multigate devices are becoming very small, which leaves minimal room for tuning their threshold voltages using different work function metals. Though dipole engineering can provide multigate devices with multiple threshold voltages while minimizing and/or eliminating the need for using different work function metals, dipole engineering techniques present challenges as device stacking is implemented to realize further scaling. Accordingly, although existing threshold voltage tuning techniques have been generally adequate for their intended purposes, they have not been entirely satisfactory in all respects.

### BRIEF DESCRIPTION OF THE DRAWINGS

The present disclosure is best understood from the following detailed description when read with the accompanying figures. It is emphasized that, in accordance with the standard practice in the industry, various features are not drawn to scale and are used for illustration purposes only. In fact, the dimensions of the various features may be arbitrarily increased or reduced for clarity of discussion.

FIG. 1 is a flow chart of a method for fabricating a semiconductor device according to various aspects of the present disclosure.

FIG. 2 is a flow chart of a method of a block of FIG. 1 according to various aspects of the present disclosure.

FIG. 3 is a flow chart of a method of a block of FIG. 2 according to various aspects of the present disclosure.

FIG. 4 is a fragmentary schematic top view of an exemplary workpiece, at a fabrication stage associated with the method of FIG. 1 according to various aspects of the present disclosure.

FIGS. 5A, 5B, 6A, 6B, 7A, 7B, 8A, 8B, 10A, 10B, 11A, 11B, 12A, 12B, 13A, 13B, 14A, and 14B are fragmentary cross-sectional views of the exemplary workpiece of FIG. 4, at various fabrication stages associated with the method of FIG. 1 according to various aspects of the present disclosure.

FIGS. 9A, 9B, 9C, and 9D are enlarged cross-sectional views of a portion of the exemplary workpiece of FIG. 8B according to various aspects of the present disclosure.

FIG. 15 is an exemplary diagram showing a first dipole patterning process that may be used in conjunction with the method of FIG. 1 according to various aspects of the present disclosure.

FIGS. 16 and 17 are exemplary diagrams showing a second dipole patterning process that may be used in conjunction with the method of FIG. 1 according to various aspects of the present disclosure.

FIGS. 18A, 18B, 19A, and 19B are fragmentary cross-sectional views of an alternative workpiece, at various fabrication stages associated with the method of FIG. 1 according to various aspects of the present disclosure.

FIG. 20 is a fragmentary cross-sectional view of another alternative workpiece that may be fabricated according to the method of FIG. 1 according to various aspects of the present disclosure.

### DETAILED DESCRIPTION

The present disclosure relates generally to integrated circuit (IC) devices, and more particularly, to methods of tuning threshold voltage (Vt) in IC devices, such as fin-like field effect transistors (FinFETs), gate-all-around (GAA) transistors, IC devices having stacked device structures, such as a transistor stack having an n-type transistor and a p-type transistor (i.e., complementary field effect transistors (CFETs)).

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact and may also include embodiments in which additional features may be formed between the first and second features, such that the first and second features may not be in direct contact. In addition, spatially relative terms, for example, “lower,” “upper,” “horizontal,” “vertical,” “above,” “over,” “below,” “beneath,” “up,” “down,” “top,” “bottom,” etc. as well as derivatives thereof (e.g., “horizontally,” “downwardly,” “upwardly,” etc.) are used for ease of the present disclosure of one features relationship to another feature. The spatially relative terms are intended to cover different orientations of the device including the features. The present disclosure may also repeat reference numerals and/or letters in the various examples. This repetition is for the purpose of simplicity and clarity and does not in itself dictate a relationship between the various embodiments and/or configurations discussed.

Further, when a number or a range of numbers is described with “about,” “approximate,” and the like, the term is intended to encompass numbers that are within a reasonable range considering variations that inherently arise during manufacturing as understood by one of ordinary skill in the art. For example, the number or range of numbers encompasses a reasonable range including the number described, such as within +/−10% of the number described, based on known manufacturing tolerances associated with manufacturing a feature having a characteristic associated with the number. For example, a material layer having a thickness of “about 5 nm” can encompass a dimension range from 4.5 nm to 5.5 nm where manufacturing tolerances associated with depositing the material layer are known to be +/−10% by one of ordinary skill in the art. Furthermore, given the variances inherent in any manufacturing process, when device features are described as having “substantial” properties and/or characteristics, such term is intended to capture properties and/or characteristics that are within tolerances of manufacturing processes. For example, “substantially vertical” or “substantially horizontal” features are intended to capture features that are approximately vertical and horizontal within given tolerances of the manufacturing processes used to fabricate such features-but not mathematically or perfectly vertical and horizontal.

An IC may include numerous transistors. Providing the IC with transistors having multiple threshold voltages (Vt) can maximize its performance and/or reliability, for example, by boosting speed/performance of some transistors of the IC while reducing power consumption of other transistors of the IC. However, providing multigate devices with multiple threshold voltages is challenging because multigate devices are becoming very small, which leaves minimal room for tuning their threshold voltages using different work function metals. Dipole engineering may flexibly provide multigate devices with different threshold voltages by incorporating dipole dopants into gate dielectrics thereof and minimize and/or eliminate the need for using different work function metals. This may obviate the need of patterning work function metals, making dipole engineering very suitable for nano-sized transistors, such as FinFETs and GAA transistors. Although existing dipole engineering techniques have been generally adequate for their intended purposes, they have not been entirely satisfactory in all respects.

The present disclosure provides dipole engineering techniques for multi-threshold voltage (Vt) tuning. In embodiments, the present disclosure provides a method of forming a p-dipole layer including an aluminum layer over a high-k dielectric layer and performing a thermal drive-in process to drive p-dipole dopants (aluminum) from the p-dipole layer into the high-k dielectric layer. The aluminum layer may be formed using an atomic layer deposition (ALD) process with precursors of aluminum chloride and trimethylaluminum. The aluminum layer includes an increased concentration (e.g., greater than 90%) of aluminum compared to an aluminum oxide layer and/or an aluminum nitride layer, which may be used as p-dipole layers. Thus, efficiency of the thermal driving of aluminum is increased, which increases Vt tuning efficiency. For example, an amount of aluminum driven into the high-k dielectric layer during a certain time and at a certain temperature is increased. This may save time and energy of dipole engineering processes. The p-dipole layer may further include an aluminum oxide layer and/or an aluminum nitride layer. The method may be used in conjunction with dipole patterning processes to form high-k dielectric layers in various portions of a semiconductor structure with various concentrations and/or compositions of p-dipole dopants. Efficiency of the multi-Vt tuning may be increased by implementing the disclosed method.

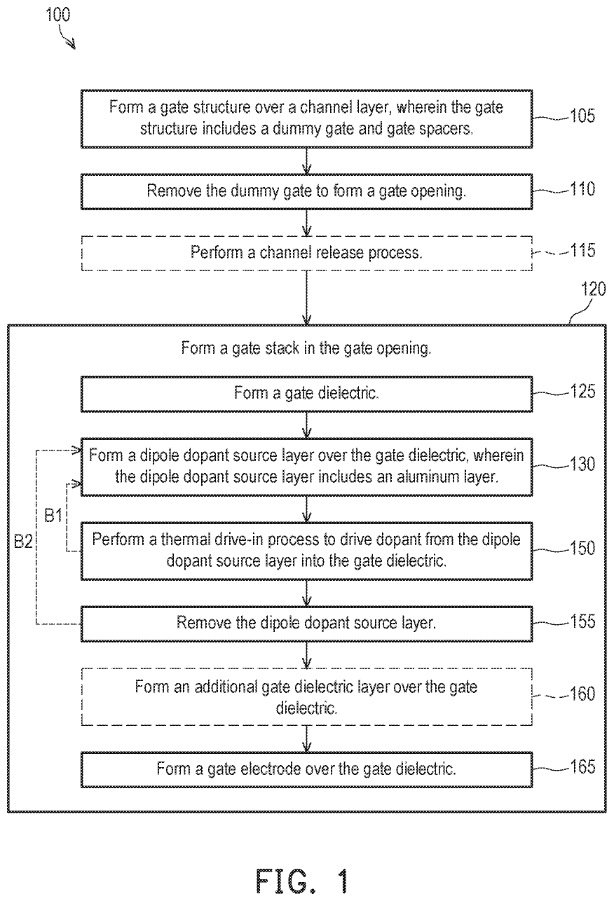

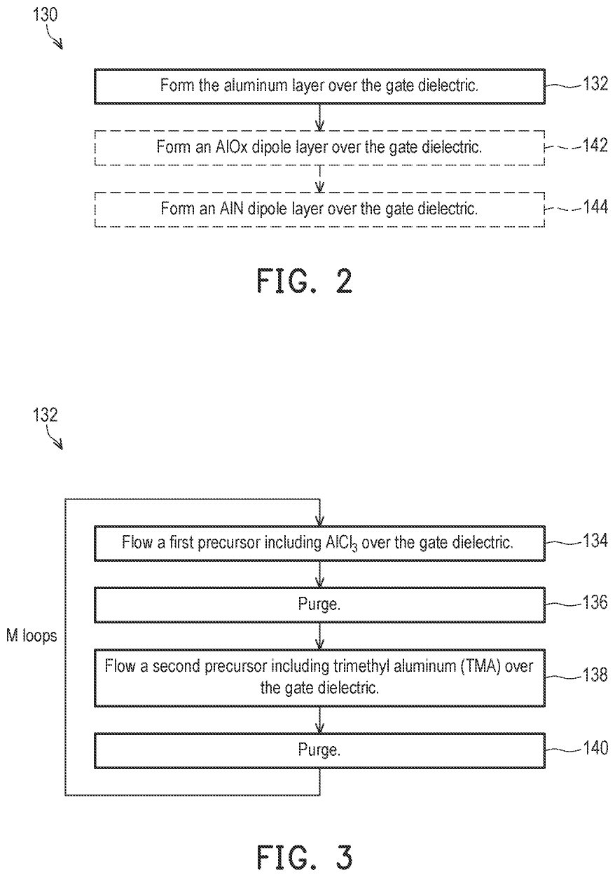

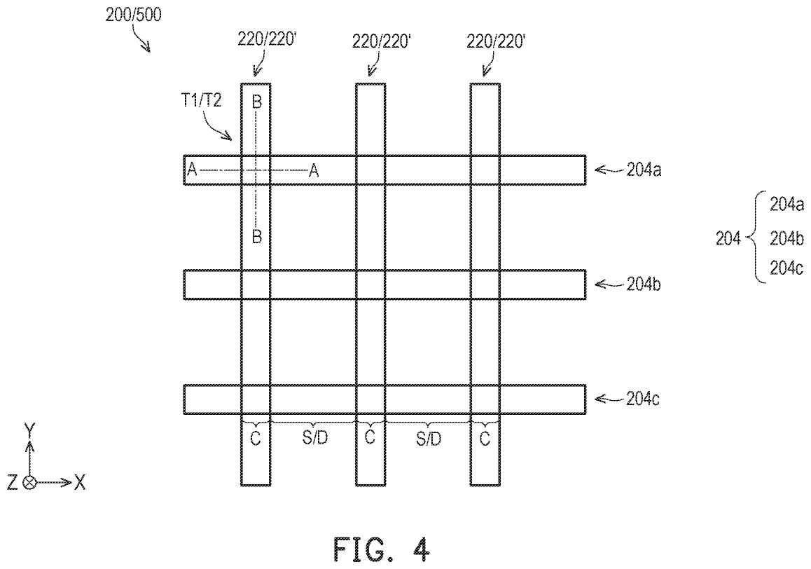

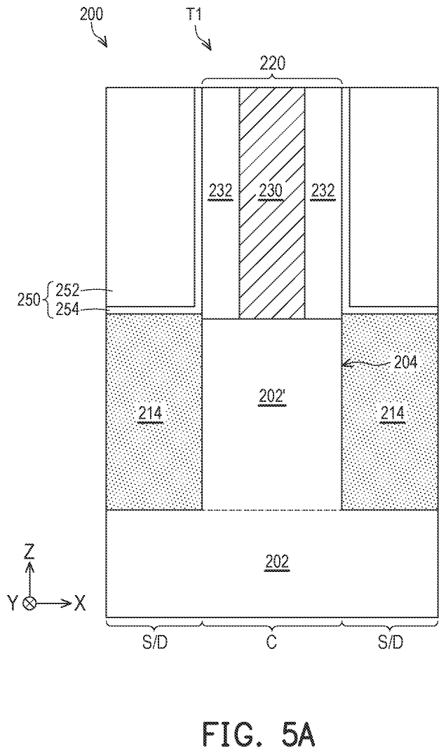

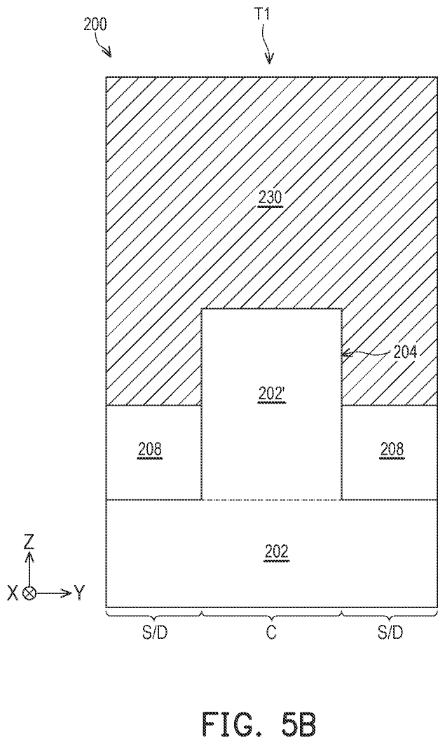

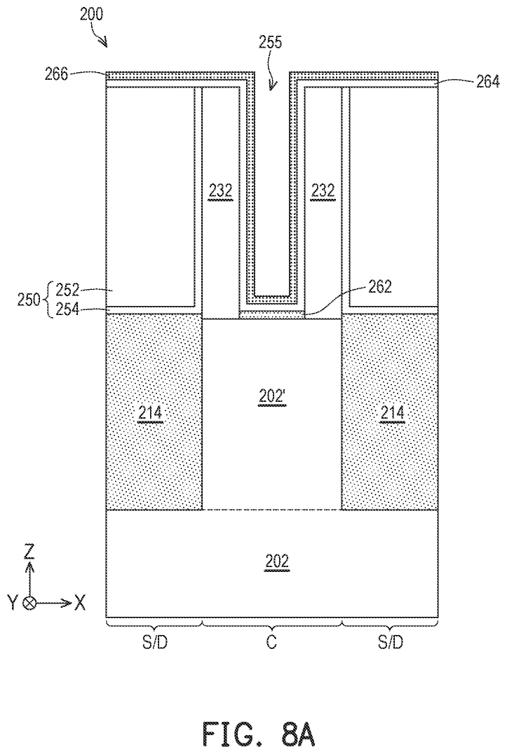

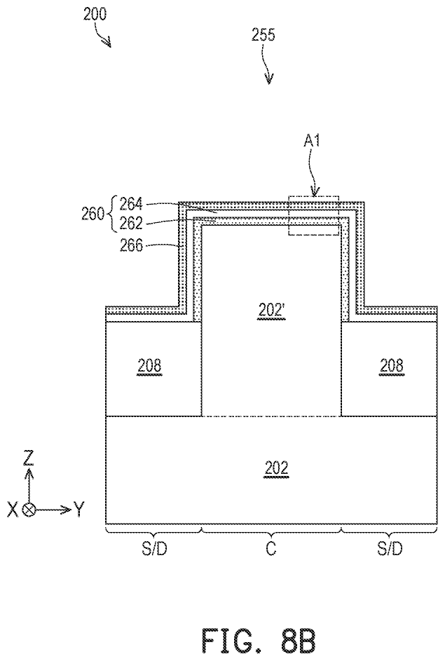

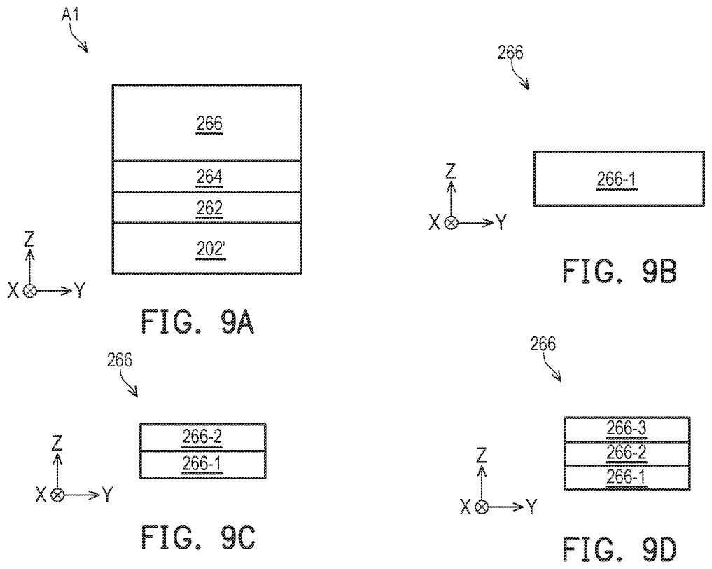

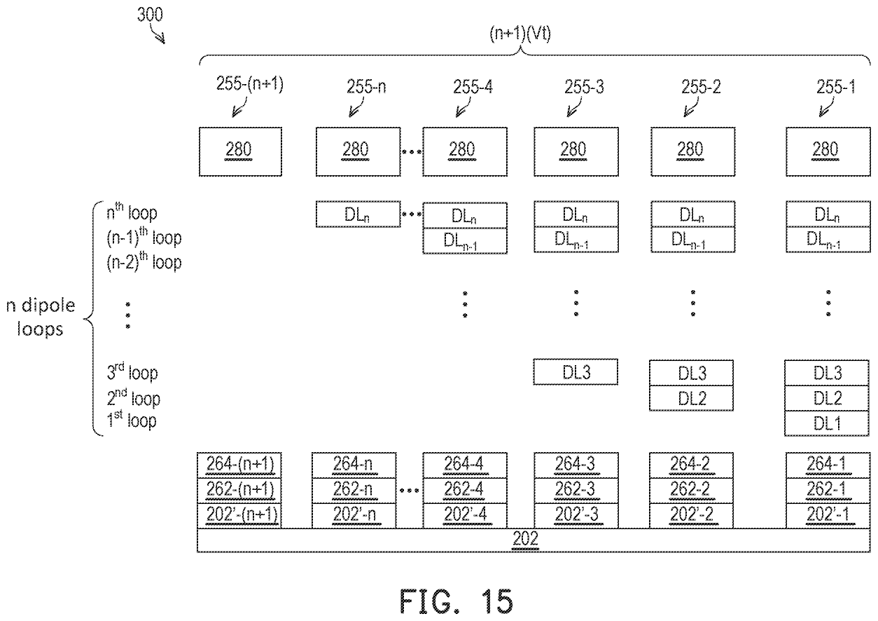

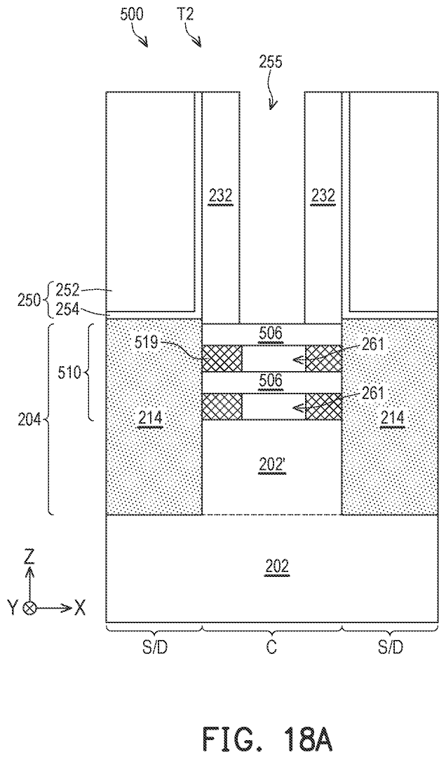

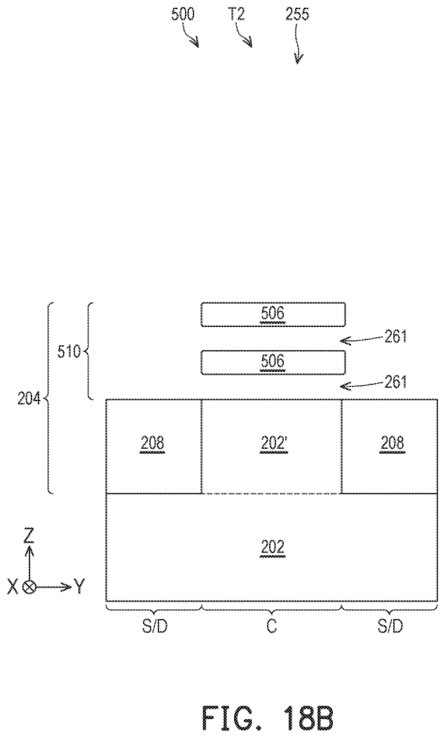

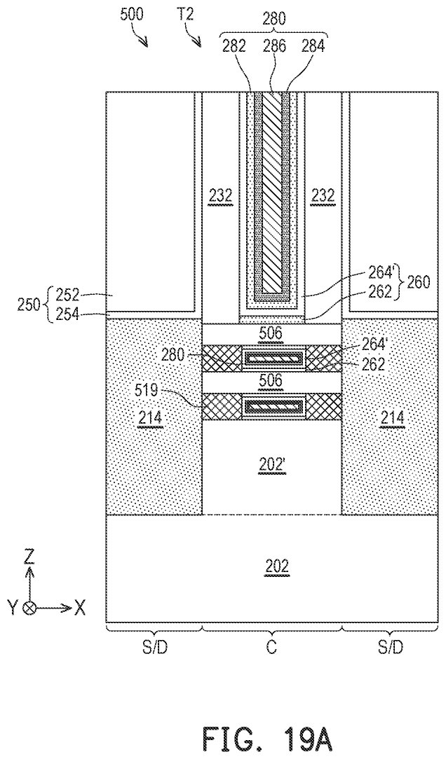

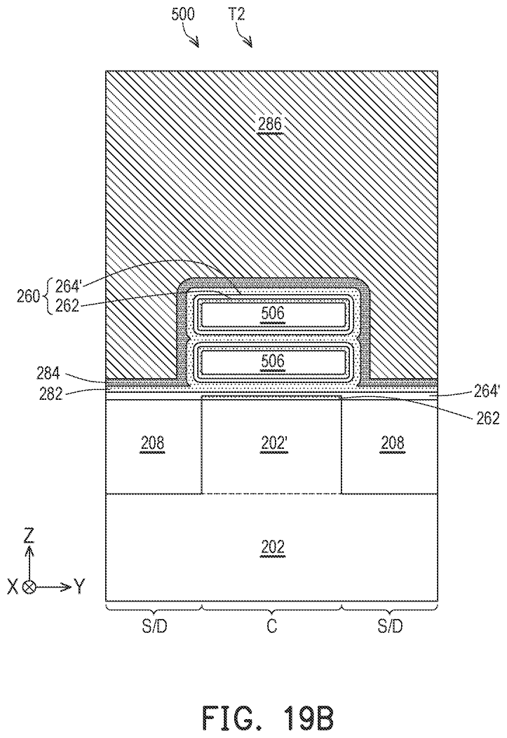

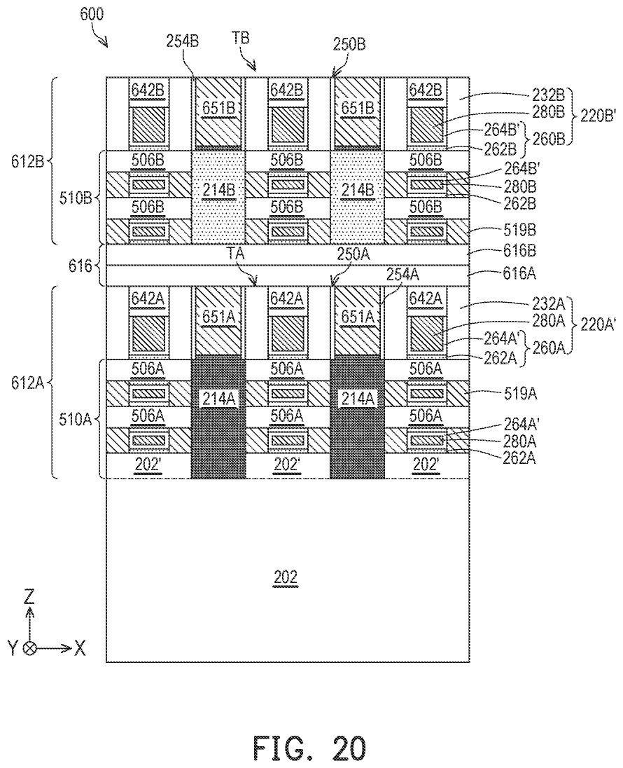

FIG. 1 is a flow chart of a method 100 for fabricating a gate stack of a transistor according to various aspects of the present disclosure. FIG. 2 is a flow chart of a method of a block of FIG. 1. FIG. 3 is a flow chart of a method of a block of FIG. 2. FIG. 4 is a fragmentary schematic top view of an exemplary workpiece 200, at a fabrication stage associated with the method 100 of FIG. 1 according to various aspects of the present disclosure. FIGS. 5A-8A and FIGS. 10A-14A are fragmentary cross-sectional views of the exemplary workpiece 200 along an A-A line of FIG. 4 at various fabrication stages associated with method 100 of FIG. 1 according to various aspects of the present disclosure. FIGS. 5B-8B and FIGS. 10B-14B are fragmentary cross-sectional views of the exemplary workpiece 200 along a B-B line of FIG. 4 at various fabrication stages associated with method 100 of FIG. 1 according to various aspects of the present disclosure. FIGS. 9A-9D are enlarged cross-sectional views of a portion of the exemplary workpiece 200 of FIG. 8B according to various aspects of the present disclosure. FIGS. 15-17 are exemplary diagrams showing a dipole patterning process 300 and a dipole patterning process 400 that may be used in conjunction with method 100 according to various aspects of the present disclosure. FIGS. 18A-19B are fragmentary cross-sectional views of an alternative workpiece 500, at various fabrication stages associated with method 100 of FIG. 1 according to various aspects of the present disclosure. FIG. 20 is a fragmentary cross-sectional view of an alternative workpiece 600 that may be fabricated according to the method 100 of FIG. 1 according to various aspects of the present disclosure. FIGS. 1-20 have been simplified for the sake of clarity to better understand the inventive concepts of the present disclosure. Additional steps can be provided before, during, and after method 100, and some of the steps described can be repeated, moved, replaced, or eliminated for additional embodiments of method 100. Because the workpieces 200, 500, and 600 will be fabricated into a semiconductor structure, the workpieces 200, 500, and 600 may be referred to herein as semiconductor structures 200, 500, and 600, respectively, as the context requires. For avoidance of doubts, the X, Y and Z directions in FIGS. 4-14B and 18A-20 are perpendicular to one another.

Referring to FIGS. 1, 4, and 5A-5B, method 100 at block 105 includes forming a gate structure over a channel layer. The gate structure includes a dummy gate and gate spacers. This can include receiving and/or forming a workpiece 200 that includes a substrate (wafer) 202, a mesa 202′ (i.e., a patterned, projecting portion of substrate 202), an isolation feature 208, epitaxial source/drains 214, a gate structure 220 (depicted as having a dummy gate 230 and gate spacers 232), and a dielectric layer 250. In embodiments, workpiece 200 includes a number of active regions 204 (e.g., active regions 204a, 204b, 204c, individually or collectively referred to as active regions 204 dependent upon the context). As depicted in FIG. 4, each active region 204 extends lengthwise along the X direction. Active regions 204 may each have a fin-like structure and thus be referred to as fins 204 or fin-like structures 204. The number of active regions 204 shown in FIG. 4 are for illustration purpose only and should not be construed as limiting the scope of the present disclosure. In the depicted embodiments, active regions 204 each include a respective mesa 202′ in a channel region C and respective epitaxial source/drains 214 in source/drain regions S/D. Mesa 202′ extends between epitaxial source/drains 214 along the X direction. In the depicted embodiment, mesa 202′ may also be referred to as channel layer or channel member 202′. Gate structure 220 is disposed over mesa 202′ and between epitaxial source/drains 214. In an X-Z plane, gate structure 220 is on a top of mesa 202′. In a Y-Z plane, gate structure 220 is on a top and sides of mesa 202′. In some embodiments, gate structures 220 and active regions 204 may form transistors (e.g., transistor T1) at their intersections in the following processes.

Substrate 202 includes an elementary semiconductor, such as silicon and/or germanium; a compound semiconductor, such as silicon carbide, gallium arsenide, gallium phosphide, indium phosphide, indium arsenide, indium antimonide, or a combination thereof; an alloy semiconductor, such as SiGe, GaAsP, AlInAs, AlGaAs, GaInAs, GaInP, GaInAsP, or a combination thereof; or a combination thereof. In the depicted embodiment, substrate 202 is a silicon substrate. In some embodiments, substrate 202 is a semiconductor-on-insulator substrate, such as a silicon-on-insulator (SOI) substrate, a silicon germanium-on-insulator (SGOI) substrate, or a germanium-on-insulator (GOI) substrate. Substrate 202 (and mesa 202′) can include various doped regions, such as p-type doped regions (e.g., p-wells), n-type doped regions (e.g., n-wells), or a combination thereof. N-type doped regions include n-type dopants, such as phosphorus, arsenic, other n-type dopant, or a combination thereof. P-type doped regions include p-type dopants, such as boron, indium, other p-type dopant, or a combination thereof. In some embodiments, the doped regions include a combination of p-type dopants and n-type dopants. The doped regions can be formed directly on and/or in substrate 202, for example, providing a p-well structure, an n-well structure, a dual-well structure, a raised structure, other suitable structure, or a combination thereof. In some embodiments, substrate 202 and mesa 202′ include an n-well, such as where transistor T1 is a p-type transistor, or a p-well, such as where transistor T1 is an n-type transistor.

Isolation feature 208 electrically isolates active device regions and/or passive device regions of a device from one another. For example, isolation feature 208 separates and electrically isolates active region 204 of transistor T1 (for example, mesa 202′ and/or epitaxial source/drains 214 thereof) from other device regions and/or devices. Isolation feature 208 includes silicon oxide, silicon nitride, silicon oxynitride, other suitable isolation material (including, for example, silicon, oxygen, nitrogen, carbon, other suitable isolation constituent, etc.), or a combination thereof. Isolation feature 208 may have a multilayer structure. For example, isolation feature 208 includes a bulk dielectric (e.g., an oxide layer) over a dielectric liner (including, for example, silicon nitride, silicon oxide, silicon oxynitride, silicon oxycarbonitride, or a combination thereof). In another example, isolation feature 208 includes a dielectric layer over a doped liner, such as a boron silicate glass (BSG) liner and/or a phosphosilicate glass (PSG) liner. Dimensions and/or characteristics of isolation feature 208 are configured to provide a shallow trench isolation (STI) structure, a deep trench isolation (DTI) structure, a local oxidation of silicon (LOCOS) structure, other suitable isolation structure, or a combination thereof. In the depicted embodiment, isolation feature 208 can be an STI.

Epitaxial source/drains 214 include a semiconductor material and can be doped with n-type dopants and/or p-type dopants. When forming a portion of a p-type transistor, such as in the depicted embodiment, epitaxial source/drains 214 can include silicon germanium or germanium doped with boron, other p-type dopant, or a combination thereof. When forming a portion of an n-type transistor, epitaxial source/drains 214 can include silicon doped with carbon, phosphorous, arsenic, other n-type dopant, or a combination thereof. Epitaxial source/drains 214 can include more than one semiconductor layer, where the semiconductor layers include the same or different materials and/or the same or different dopant concentrations. Epitaxial source/drains 214 can include materials and/or dopants that achieve desired tensile stress and/or compressive stress in channel region C. In some embodiments, doped regions, such as heavily doped source/drain (HDD) regions, lightly doped source/drain (LDD) regions, other doped regions, or a combination thereof, are disposed in epitaxial source/drains 214. In some embodiments, doped regions, such as LDD regions, may extend into channel region C. As used herein, source/drain region, epitaxial source/drain, epitaxial source/drain feature, etc. may refer to a source of transistor and/or a device, a drain of a transistor and/or a device, or a source and/or a drain of multiple devices (e.g., including of transistor T1 and/or device T1).

Dummy gate 230 extends lengthwise in a direction that is different than (e.g., orthogonal to) the lengthwise direction of active region 204. For example, dummy gate 230 extends lengthwise along the Y direction, having a length along the Y direction, a width along the X direction, and a height along the Z direction. In the X-Z plane, dummy gate 230 is disposed on a top of mesa 202′. In the Y-Z plane, dummy gate 230 is disposed over a top and sidewalls of mesa 202′. Dummy gate 230 can include a dummy gate electrode and a dummy gate dielectric. The dummy gate electrode includes a suitable dummy gate material, and the dummy gate dielectric includes a suitable dielectric material. For example, the dummy gate electrode includes polysilicon (i.e., a poly gate) and the dummy gate dielectric includes silicon oxide (i.e., a dummy oxide). Dummy gate 230 can include additional layers, such as a hard mask layer, a capping layer, other suitable layer, or a combination thereof.

Gate spacers 232 are adjacent to and along sidewalls of dummy gate 230. Gate spacers 232 can include seal spacers, offset spacers, sacrificial spacers, dummy spacers, main spacers, other suitable spacers, or a combination thereof. Gate spacers 232 can have single layer structures or multilayer structures. Gate spacers 232 include a dielectric material, which can include silicon, oxygen, carbon, nitrogen, other suitable constituent, or a combination thereof (e.g., silicon oxide, silicon nitride, silicon oxynitride, silicon carbide, silicon carbonitride, silicon oxycarbide, silicon oxycarbonitride, etc.). For example, gate spacers 232 can include silicon, oxygen, nitrogen, carbon, and hydrogen (i.e., gate spacers 232 are SiONCH layers).

Dielectric layer 250 is disposed over substrate 202, isolation feature 208, epitaxial source/drains 214, and gate structure 220. Dielectric layer 250 can have a multilayer structure, such as an ILD layer 252 over a contact etch stop layer (CESL) 254. ILD layer 252 includes a dielectric material including, for example, silicon oxide, carbon doped silicon oxide, silicon nitride, silicon oxynitride, tetraethyl orthosilicate (TEOS)-formed oxide, BSG, PSG, borophosphosilicate glass (BPSG), fluorosilicate glass (FSG), xerogel, aerogel, amorphous fluorinated carbon, parylene, benzocyclobutene-based (BCB) dielectric material, polyimide, other suitable dielectric material, or a combination thereof. In some embodiments, ILD layer 252 includes a dielectric material having a dielectric constant that is less than a dielectric constant of silicon dioxide (e.g., k<3.9). In some embodiments, ILD layer 252 includes a dielectric material having a dielectric constant that is less than about 2.5 (i.e., an extreme low-k dielectric material), such as porous silicon oxide, silicon carbide, carbon-doped oxide (e.g., an SiCOH-based material (having, e.g., Si—CH₃ bonds)), or a combination thereof, each of which is tuned/configured to have a dielectric constant less than about 2.5. CESL 254 includes a dielectric material that is different than the dielectric material of ILD layer 252. For example, where ILD layer 252 includes a low-k dielectric material (e.g., porous silicon oxide), CESL 254 can include silicon and nitrogen, such as silicon nitride, silicon carbonitride, or silicon oxycarbonitride.

Forming dielectric layer 250 can include depositing a dielectric material over substrate 202, isolation feature 208, epitaxial source/drains 214, and gate structure 220 and performing a planarization process, such as a chemical mechanical polishing (CMP), on the dielectric material. The planarization process removes any dielectric material from over gate structure 220. Dummy gate 230 can function as a planarization stop layer, and the planarization process can be performed until reaching dummy gate 230. The planarization process can planarize a top surface of dielectric layer 250 and a top surface of gate structure 220. In some embodiments, dielectric layer 250 is a device-level dielectric layer of a multilayer interconnect (MLI) feature, which electrically connects devices (for example, transistors, resistors, capacitors, inductors, etc.), components of devices (for example, gates and/or source/drains), devices within the MLI feature, components of the MLI feature, or a combination thereof, such that the devices and/or components can operate as specified by design requirements.

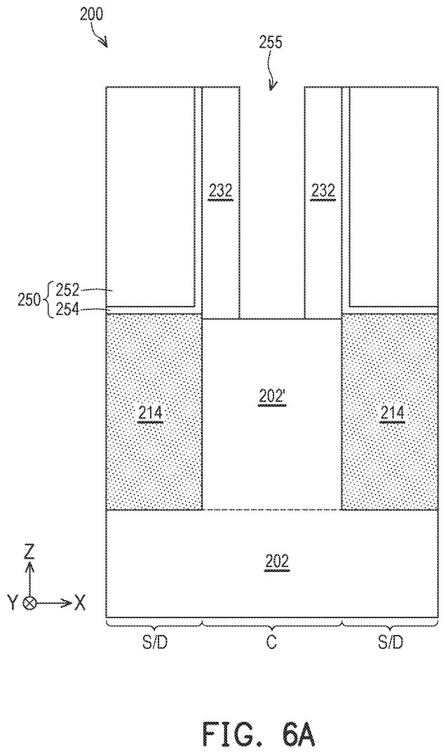

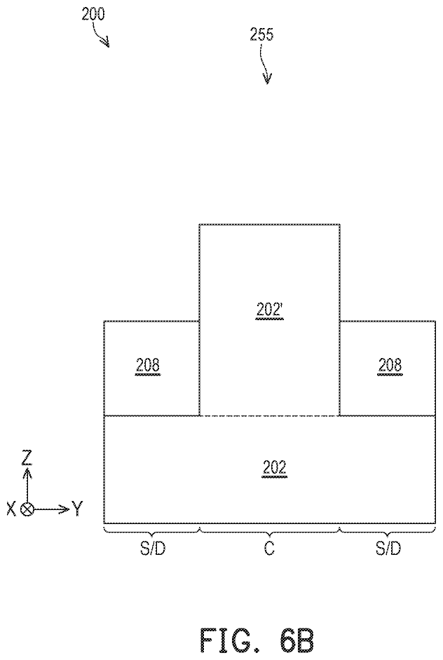

Referring to FIGS. 1 and 6A-6B, method 100 at block 110 includes removing dummy gate 230 to form a gate opening 255. In the depicted embodiment, gate opening 255 exposes mesa 202′. Gate opening 255 has sidewalls formed by gate spacers 232 and a bottom formed by mesa 202′ and/or isolation feature 208. Gate opening 255 may also be referred as gate region 255. In some embodiments, an etching process selectively removes dummy gate 230 with respect to gate spacers 232, dielectric layer 250, or a combination thereof. For example, the etching process substantially removes dummy gate 230 but does not remove, or does not substantially remove, gate spacers 232, isolation feature 208, dielectric layer 250, mesa 202′, etc. In some embodiments, an etchant is selected for the etching process that etches polysilicon (i.e., dummy gate 230) at a higher rate than dielectric materials (i.e., gate spacers 232, dielectric layer 250, etc.) and semiconductor materials (i.e., mesa 202′) (i.e., the etchant has a high etch selectivity with respect to polysilicon). The etching process is a dry etch, a wet etch, other suitable etch, or a combination thereof. In some embodiments, a patterned mask layer (an etch mask) covers and protects dielectric layer 250 and/or gate spacers 232 but exposes dummy gate 230 during the etching process.

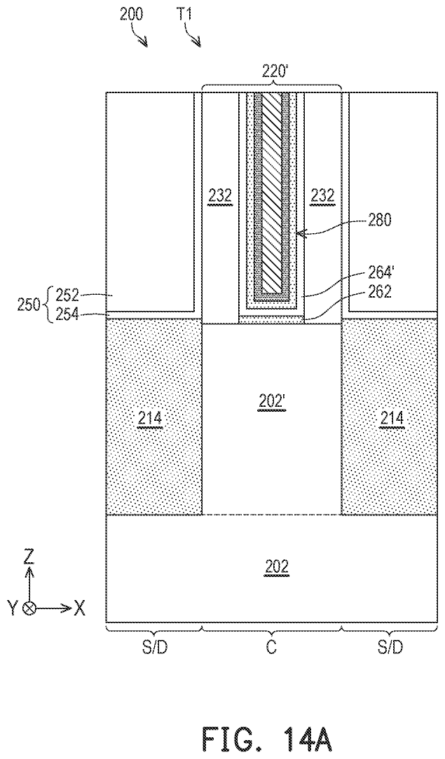

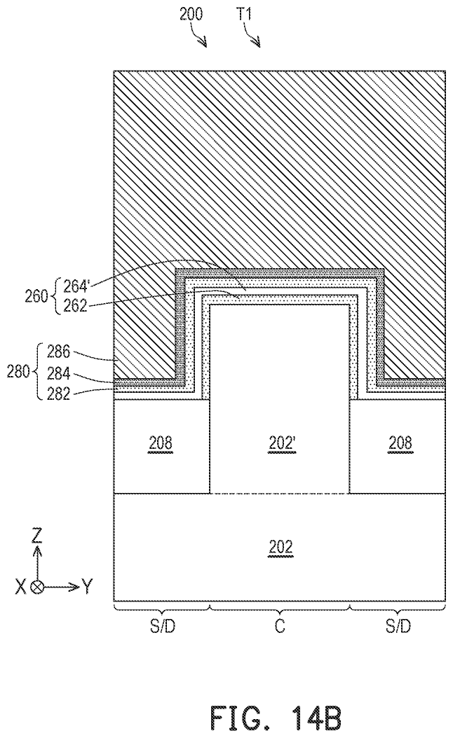

Referring to FIGS. 1 and 7A-14B, method 100 at block 120 includes forming a gate stack in gate opening 255. The gate stack includes a gate dielectric 260 (e.g., at least one dielectric gate layer, such as a high-k dielectric layer) and a gate electrode 280 (e.g., at least one electrically conductive gate layer, such as a work function layer and/or a bulk metal layer). The gate stack fills gate opening 255 (see FIG. 14A and FIG. 14B). In the X-Z plane (FIG. 14A), the gate stack is disposed between gate spacers 232. In the Y-Z plane (FIG. 14B), the gate stack partially surrounds mesa 202′ (e.g., covers a top surface and sidewalls of mesa 202′). The gate stack may include numerous other layers, such as a capping layer, an interface layer, a diffusion layer, a barrier layer, a hard mask layer, or a combination thereof. The gate stack and gate spacers 232 are collectively referred to as a gate structure 220′.

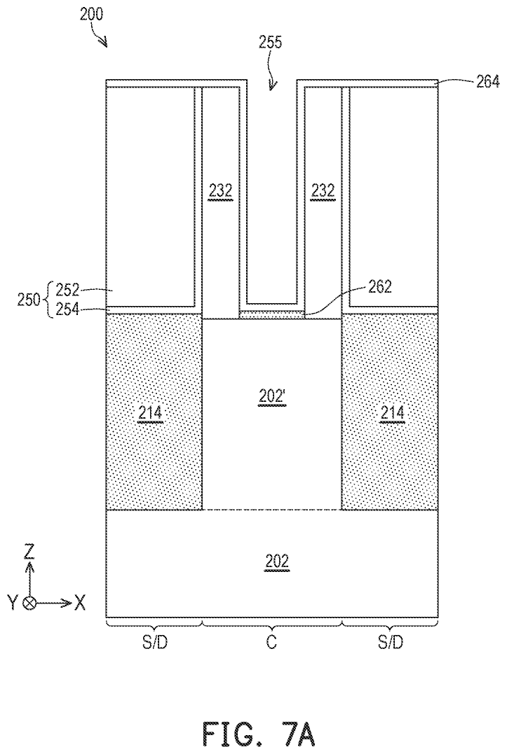

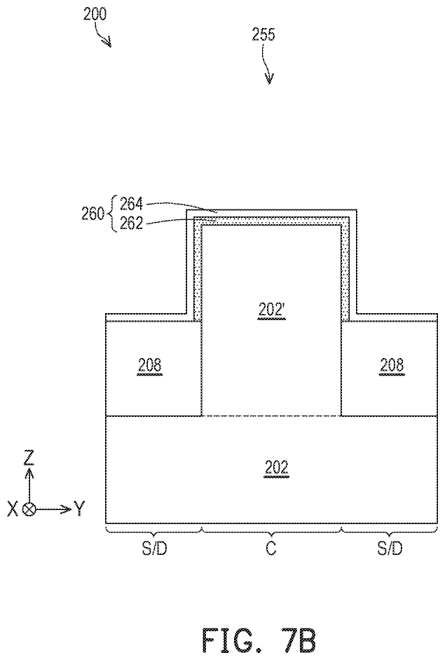

Referring to FIGS. 1 and 7A-7B, method 100 at block 125 includes forming a gate dielectric, such as gate dielectric 260 in gate opening 255 and over mesa 202′. In the depicted embodiment, gate dielectric 260 includes an interfacial layer 262 and a gate dielectric layer 264. Interfacial layer 262 partially fills gate opening 255 and is formed on semiconductor surfaces, such that interfacial layer 262 is between mesa 202′ and gate dielectric layer 264. In the X-Z plane, interfacial layer 262 covers top surfaces of mesa 202′. In the Y-Z plane, interfacial layer 262 partially surrounds mesa 202′ (e.g., covers a top surface and sidewalls of mesa 202′). Interfacial layer 262 is formed by thermal oxidation, chemical oxidation, atomic layer deposition (ALD), chemical vapor deposition (CVD), other suitable process, or a combination thereof.

Interfacial layer 262 includes a dielectric material, such as SiO₂, SiGeOₓ, HfSiO, SiON, other dielectric material, or a combination thereof. In some embodiments, interfacial layer 262 is a group IV-based oxide layer, which generally refers to an oxide of a group IV-based material (i.e., a material that includes at least one group IV element, such as Si, Ge, C, etc.). In some embodiments, interfacial layer 262 is a group III-V-based oxide layer, which generally refers to an oxide of a group III-V-based material (i.e., a material that includes at least one group III element, such as Al, Ga, In, B, etc., and at least one group V element, such as N, P, As, Sb, etc.). A thickness of interfacial layer 262 is less than a thickness of gate dielectric layer 264. In some embodiments, a thickness of interfacial layer 262 is about 0.5 nm to about 2 nm. In the depicted embodiment, interfacial layer 262 has a substantially uniform thickness.

Gate dielectric layer 264 partially fills gate opening 255 and is formed on interfacial layer 262, gate spacers 232, isolation feature 208, and dielectric layer 250. In the X-Z plane, gate dielectric layer 264 has a u-shaped profile in a top portion of gate opening 255. In the Y-Z plane, gate dielectric layer 264 partially surrounds mesa 202′. Gate dielectric layer 264 has a substantially uniform thickness. In some embodiments, a thickness of gate dielectric layer 264 is about 1 nm to about 5 nm. Gate dielectric layer 264 is formed by ALD, CVD, physical vapor deposition (PVD), an oxide-based deposition process, other suitable process, or a combination thereof.

Gate dielectric layer 264 includes a high-k dielectric material, which generally refers to dielectric materials having a dielectric constant that is greater than a dielectric constant of silicon dioxide (k˜3.9), such as HfO₂, HfSiO, HfSiO₄, HfSiON, HfLaO, HfTaO, HfTiO, HfZrO, HfAlOₓ, ZrO, ZrO₂, ZrSiO₂, AlO, AlSiO, Al₂O₃, TIO, TiO₂, LaO, LaSiO, La₃, La₂O₃, Ta₂O₂, Ta₂O₅, Y₂O₃, SrTiO₃, BaZrO, BaTiO₃ (BTO), (Ba,Sr) TiO₃ (BST), Si₃N₄, HfO₂—Al₂O₃, other high-k dielectric material, or a combination thereof. For example, gate dielectric layer 264 is a hafnium-based oxide (e.g., HfO₂) layer or a zirconium-based oxide (e.g., ZrO₂) layer. In some embodiments, gate dielectric layer 264 has a multilayer structure.

Referring to FIGS. 1 and 8A-11B, dipole engineering is implemented after forming gate dielectric 260 to modulate a threshold voltage of transistor T1. For example, processing associated with blocks 130, 150, and 155 of method 100 can form dipoles in gate dielectric 260 that shift the threshold voltage of transistor T1. In some embodiments, processing associated with block 130, block 150, and block 155, or a combination thereof is repeated, such as illustrated by arrows B1 and B2. The dipoles can form in gate dielectric layer 264, and parameters of the processing associated with blocks 130, 150, and 155 of method 100 can be tuned to achieve desired threshold voltage shifts in and/or desired threshold voltage characteristics of transistor T1. In the depicted embodiment, p-dipole dopant is incorporated into gate dielectric 260 to change (e.g., decrease) the threshold voltage of transistor T1, which is configured as a p-type transistor or an n-type transistor. In some embodiments, transistor T1 is configured as a p-type transistor. As described below, the disclosed dipole engineering technique is a threshold voltage tuning process with increased efficiency.

Referring to FIGS. 1 and 8A-8B, method 100 at block 130 includes forming a dipole dopant source layer 266 over gate dielectric 260. Dipole dopant source layer 266 is formed on gate dielectric layer 264 and partially fills gate opening 255. In the X-Z plane, dipole dopant source layer 266 covers gate dielectric layer 264 and has a u-shaped profile in a top portion of gate opening 255. In the Y-Z plane, dipole dopant source layer 266 covers gate dielectric layer 264 (e.g., on exposed surfaces) and partially surrounds mesa 202′.

In some embodiments, dipole dopant source layer 266 is a metal-containing layer that includes p-dipole dopant(s) that can be driven into gate dielectric layer 264 to change a threshold voltage of transistor T1. For example, dipole dopant source layer 266 includes a p-dipole dopant (e.g., a metal). In some embodiments, dipole dopant source layer 266 includes chlorine, oxygen, nitrogen, carbon, or a combination thereof (e.g., a non-metal). In some embodiments, the p-dipole dopant is aluminum (Al) and dipole dopant source layer 266 includes an aluminum layer.

FIG. 9A shows an enlarged view of a portion Al of workpiece 200 in FIG. 8B and FIGS. 9B-9D show enlarged views of dipole dopant source layer 266 of FIG. 9A. In the depicted embodiment of FIG. 9B, dipole dopant source layer 266 includes a single layer 266-1. The single layer 266-1 is an Al layer. In some embodiments, the Al layer includes equal to or greater than 90% of Al. In some embodiments, the Al layer includes equal to or greater than 95% of Al. If Al in the Al layer is too low (e.g., less than 90%), benefits (e.g., diffusion efficiency increases) from the Al layer may be too small. The Al layer may include less than about 10% of chlorine, carbon, oxygen, or combinations thereof.

In the depicted embodiment of FIG. 9C, dipole dopant source layer 266 includes a sublayer 266-1 and a sublayer 266-2. In some embodiments, sublayers 266-1 and 266-2 include an Al layer as described above and an aluminum oxide (AlOₓ) layer. x may be in a range of about 1 to about 1.5. The Al layer and the AlOₓ layer may be disposed in any sequence from gate dielectric layer 264. In an example, the AlOₓ layer is disposed on surfaces of gate dielectric layer 264 and the Al layer is disposed over the AlOₓ layer (i.e., sublayer 266-1 is the AlOₓ layer and sublayer 266-2 is the Al layer). In another example, the Al layer is disposed on surfaces of gate dielectric layer 264 and the AlOₓ layer is disposed over the Al layer (i.e., sublayer 266-1 is the Al layer and sublayer 266-2 is the AlOₓ layer). In some embodiments, sublayers 266-1 and 266-2 include an Al layer as described above and an aluminum nitride (AlN) layer. The Al layer and the AlN layer may be disposed in any sequence from gate dielectric layer 264. In an example, the AlN layer is disposed on surfaces of gate dielectric layer 264 and the Al layer is disposed over the AlN layer (i.e., sublayer 266-1 is the AIN layer and sublayer 266-2 is the Al layer). In another example, the Al layer is disposed on surfaces of gate dielectric layer 264 and the AlN layer is disposed over the Al layer (i.e., sublayer 266-1 is the Al layer and sublayer 266-2 is the AlN layer).

In the depicted embodiment of FIG. 9D, dipole dopant source layer 266 includes three sublayers, such as sublayer 266-1, sublayer 266-2, and a sublayer 266-3. Sublayers 266-1, 266-2, and 266-3 may include an Al layer, an AlOₓ layer, and an AlN layer as described above. The Al layer, the AlOₓ layer, and the AlN layer may be in any sequence from gate dielectric layer 264. For example, the Al layer is disposed on surfaces of gate dielectric layer 264, the AlN layer is disposed over the Al layer, and the AlOₓ layer is disposed over the AlN layer (i.e., sublayer 266-1 is the Al layer, sublayer 266-2 is the AlN layer, and sublayer 266-3 is the AlOₓ layer). In another example, the AlN layer is disposed on surfaces of gate dielectric layer 264, the Al layer is disposed over the AlN layer, and the AlOₓ layer is disposed over the Al layer (i.e., sublayer 266-1 is the AlN layer, sublayer 266-2 is the Al layer, and sublayer 266-3 is the AlOₓ layer). In yet another example, the AlOₓ layer is disposed on surfaces of gate dielectric layer 264, the Al layer is disposed over the AlOₓ layer, and the AlN layer is disposed over the Al layer (i.e., sublayer 266-1 is the AlOₓ layer, sublayer 266-2 is the Al layer, and sublayer 266-3 is the AlN layer).

The present disclosure contemplates other sequences and combinations of the Al layer with the AlOₓ layer and/or the AlN layer. For example, the Al layer is sandwiched between two of the AlOₓ layers (i.e., sublayer 266-1 is a first AlOₓ layer, sublayer 266-2 is the Al layer, and sublayer 266-3 is a second AlOₓ layer). In another example, the Al layer is sandwiched between two of the AlN layers (i.e., sublayer 266-1 is a first AlN layer, sublayer 266-2 is the Al layer, and sublayer 266-3 is a second AlN layer). In some embodiments, dipole dopant source layer 266 includes more than three sublayers. In some embodiments, dipole dopant source layer 266 includes other types of sublayers, such as other metal oxide layers, other metal nitride layers. In the disclosed combinations, at least one of the sublayers is an Al layer.

Dipole dopant source layer 266 may be formed using any suitable method. Referring to FIG. 2, in some embodiments, block 130 includes a method including a block 132 where the Al layer is formed over gate dielectric layer 264. In some embodiments, the Al layer may be formed using a deposition temperature of about 300° C. to about 480° C. In some embodiments, the Al layer may be formed using a pressure of about 2 torr to about 50 torr. In some embodiments, the Al layer may be formed by an ALD process that flows a first precursor and a second precursor sequentially over gate dielectric layer 264. Referring to FIG. 3, method of block 132 may include a block 134, flowing a first precursor (e.g., a first precursor gas) including aluminum chloride (AlCl₃) over gate dielectric layer 264 in a process chamber. Molecules of the first precursor may adsorb on surfaces of workpiece 200 (e.g., surfaces of gate dielectric layer 264). In some embodiments, the first precursor forms a first monolayer on the surfaces of gate dielectric layer 264. After flowing the first precursor, a first purge process at block 136 using an inert gas such as argon (Ar) or nitrogen (N₂) is performed to purge excess first precursor and/or any by-products from the chamber. The method of block 132 may further include a block 138, which includes flowing a second precursor (e.g., a second precursor gas) including trimethylaluminum (TMA) over gate dielectric layer 264 in the process chamber. In some embodiments, molecules of the second precursor adsorb on surfaces of the workpiece 200 (e.g., the first monolayer). In some embodiments, the second precursor forms a second monolayer on the first monolayer. The second precursor (e.g., in the second monolayer) may react with the first precursor (e.g., in the first monolayer) to form an Al sublayer. Without being limited by theory, the reaction is a surface reaction. In some embodiments, the Al sublayer is a monolayer. After flowing the second precursor, a second purge process at block 140 using an inert gas such as Ar or N₂ is performed to purge excess second precursor and/or any by-products from the chamber. Blocks 134, 136, 138, and 140 may be repeated for M loops to form multiple Al sublayers, which collectively form the Al layer and a total thickness of the Al sublayers meets a designed thickness of the Al layer. M is an integer. In some embodiments, the method of block 132 in FIG. 3 is an ALD process, and blocks 134, 136, 138, and 140 may be a cycle of an ALD process. The cycle of the ALD process may be repeated until the Al layer has a desired thickness.

Referring back to FIG. 2, method of block 130 optionally further includes a block 142 where an AlOₓ dipole layer is formed over the gate dielectric, such as the AlOₓ layer formed over gate dielectric layer 264 as described above, and/or a block 144 where an AlN dipole layer is formed over the gate dielectric, such as the AlN layer formed over gate dielectric layer 264 as described above. The forming of the AlOₓ layer and the forming of the AlN layer may include any suitable method, such as an ALD process and/or a CVD process.

At blocks 132, 142, and 144, workpiece 200 may be inside a same chamber or in different chambers. The forming of the Al layer, the AlOₓ layer, and the AlN layer may be in a vacuum environment (e.g., 2 torr to 50 torr). In some embodiments, between the forming of two adjacent sublayers, method of block 130 may include breaking vacuum (may be referred to as having a vacuum break), where the workpiece 200 is moved into a non-vacuum environment (e.g., atmosphere). For example, vacuum may be broken between forming the Al layer and the AlOₓ layer and/or the AlN layer. The non-vacuum environment may include oxygen and/or water steam. Block 132, block 142, and block 144 may be in any suitable sequences, depending on the sequence of the Al layer, the AlN layer, and the AlOₓ layer over gate dielectric layer 264.

Dipole dopant source layer 266 may have a substantially uniform thickness. In some embodiments, a thickness of dipole dopant source layer 266 is about 0.3 nm to about 4 nm. If dipole dopant source layer 266 is too thin (such as less than 0.3 nm), it may not uniformly cover gate dielectric layer 264, which can affect uniformity of dipole engineering of gate dielectric layer 264 and/or uniformity of threshold voltage tuning of transistor T1 (i.e., non-uniform threshold voltage tuning may occur). If dipole dopant source layer 266 is too thick (such as greater than 4 nm), it may be difficult to remove and thus undesirably remain in the gate stack. For example, if too thick, remnants of dipole dopant source layer 266 may remain on channel layer 202′. This can affect subsequent fabrication, for example, by leaving insufficient space for a gate electrode (such as a work function metal and/or a bulk metal layer) to fill gate opening 255 and/or cause transistor T1 to have different electrical characteristics than intended (e.g., different threshold voltage). Further, a composition and a thickness of dipole dopant source layer 266 can be designed based on a desired amount of threshold voltage tuning. For example, a thicker dipole dopant source layer 266 can provide greater threshold voltage changes in transistor T1. In embodiments, each of the sublayers (e.g., the Al layer, the AlN layer, and the AlOₓ layer) has a uniform thickness. In some embodiments, a composition and a thickness of each sublayer can be designed together to achieve desired threshold voltage.

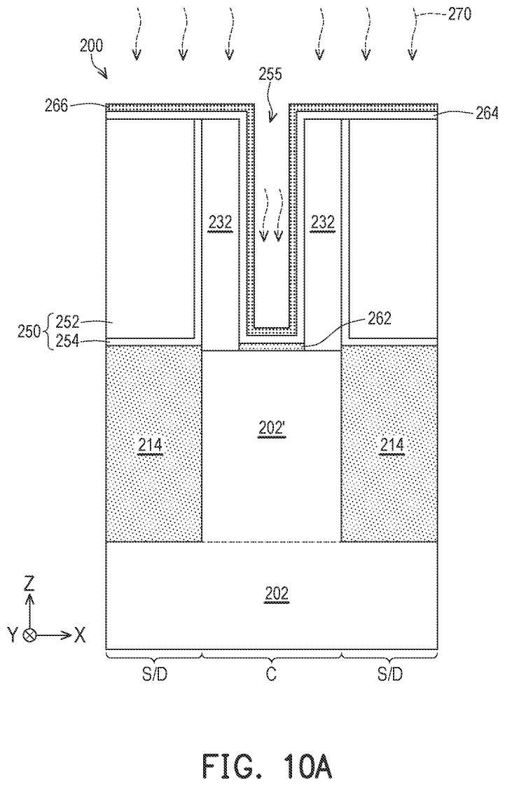

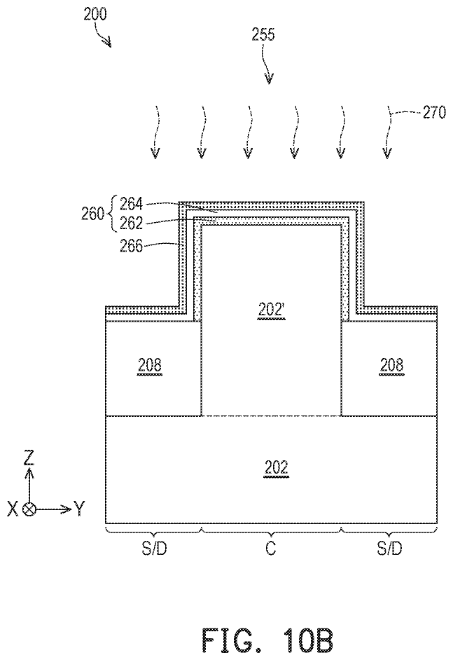

Referring to FIGS. 1 and 10A-10B, method 100 at block 150 includes performing a thermal drive-in process 270 that drives (diffuses) dopant from dipole dopant source layer 266 into gate dielectric layer 264. For example, thermal drive-in process 270 drives p-dipole dopant (e.g., Al) from dipole dopant source layer 266 into gate dielectric layer 264. Thermal drive-in process 270 can be an annealing process, such as a rapid thermal annealing (RTA), a millisecond annealing (MSA), a microsecond annealing (μSA), a microwave annealing, a laser annealing, a spike annealing, a soak annealing, a furnace annealing, other suitable annealing process, or a combination thereof. In some embodiments, thermal drive-in process 270 is performed in an inert gas ambient, including, for example, argon (Ar), helium (He), nitrogen (N₂), other inert gas, or a combination thereof. In the depicted embodiment, Al may be driven from the Al layer into gate dielectric layer 264. In some embodiments, Al may also be driven from the AlOₓ layer and/or the AlN layer into gate dielectric layer 264 depending on what sublayers are included in dipole dopant source layer 266. Without being limited by theory, because association energy of Al in the Al layer is smaller than association energy of Al in the AlOₓ layer and/or the AlN layer, Al diffusion efficiency from the Al layer is greater than that from the AlOₓ layer and/or the AlN layer. Without being limited by theory, because of relatively low association energy of Al in the Al layer, average association energy of Al in dipole dopant source layer 266 is reduced, which increases Al diffusion efficiency. In other words, by having the Al layer, efficiency of diffusion of Al from dipole dopant source layer 266 to gate dielectric layer 264 may be increased. For example, at a certain temperature and during a certain time, an increased amount of Al may diffuse from dipole dopant source layer 266 into gate dielectric layer 264. In some embodiments, an amount of Al that diffuses from the Al layer into gate dielectric layer 264 may be greater than an amount of Al that diffuses from the AlOₓ layer and/or the AlN layer into gate dielectric layer 264. In some embodiments, during a certain time to diffuse a certain amount of Al, temperature required for thermal drive-in process 270 may be reduced. Thus, increased efficiency may reduce time and/or reduce temperature of thermal drive-in process 270, which may save time of manufacturing of semiconductor devices and/or reduce impact on existing structures of transistor T1 and/or of surrounding structures and is yet sufficient to cause p-dipole dopant to migrate (or diffuse) into gate dielectric layer 264.

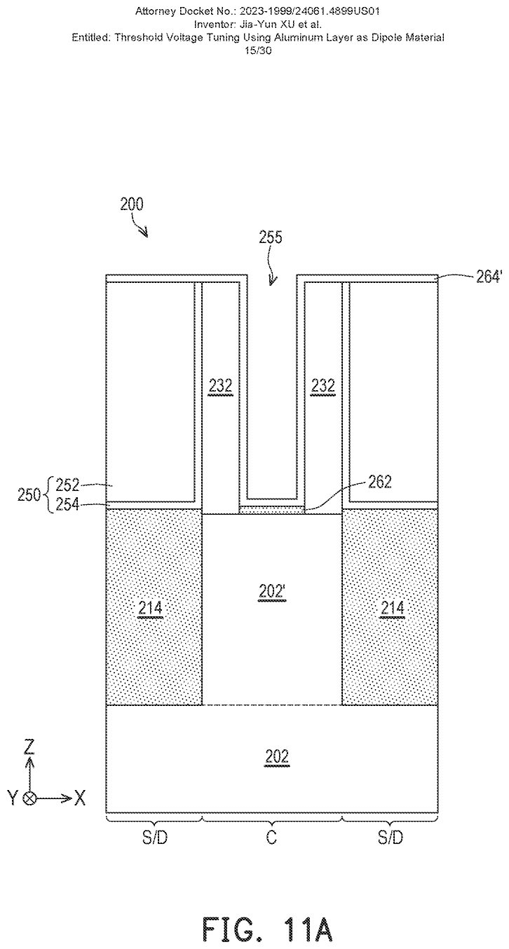

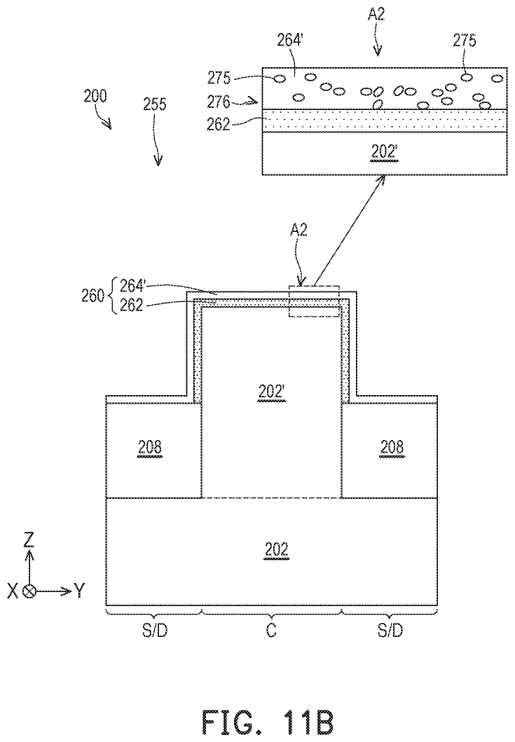

After thermal drive-in process 270, because p-dipole dopant is driven into gate dielectric layer 264, gate dielectric layer 264 becomes gate dielectric layer 264′ (i.e., a doped gate dielectric layer), as depicted in FIGS. 11A-11B. For example, gate dielectric layer 264′ is a high-k dielectric layer, such as a hafnium-based oxide (e.g., HfO₂) layer or a zirconium-based oxide (e.g., ZrO₂) layer, that further includes Al. In some embodiments, p-dipole dopant (e.g., Al) is also diffused into interfacial layer 262, such that interfacial layer 262 becomes doped interfacial layer 262. For example, doped interfacial layer 262 may be a dielectric layer, such as a group IV-based oxide (e.g., SiO₂) layer or a group III-V-based oxide layer, that further includes Al.

Referring to FIGS. 1 and 11A-11B, method 100 at block 155 includes removing dipole dopant source layer 266. By removing dipole dopant source layer 266, the disclosed dipole engineering process provides volume-free threshold voltage tuning. In other words, the dipole engineering process can modulate threshold voltage of transistor T1 by driving p-dipole dopant (e.g., Al) into gate dielectric layer 264, but material layers used for such threshold voltage modulation do not remain and thus do not consume any volume of a final gate stack, such that dimensions of gate opening 255 are maximized for subsequent gate electrode formation. In some embodiments, an etching process selectively removes dipole dopant source layer 266 with respect to gate dielectric layer 264′. For example, the etching process substantially removes dipole dopant source layer 266 but does not remove, or does not substantially remove, gate dielectric layer 264′. In some embodiments, an etchant is selected for the etching process that etches dipole dopant source layer 266 (e.g., an A1 layer alone or in combination with an AlN layer and/or an AlOₓ layer) at a higher rate than gate dielectric layer 264′ (e.g., an HfO₂ layer, a ZrO₂ layer, or another high-k dielectric material that includes A1). The etching process is a dry etch, a wet etch, other suitable etch, or a combination thereof. As shown in an enlarged view of portion A2 in FIG. 11B, p-dipole dopants 275 (e.g., A1) have diffused into gate dielectric layer 264.

A thickness of gate dielectric layer 264 is designed so that p-dipole dopant can effectively permeate through gate dielectric layer 264 to an interface 276 of gate dielectric layer 264 and interfacial layer 262. Further, a composition and/or a thickness of dipole dopant source layer 266, a composition and/or a thickness of gate dielectric layer 264, and parameters of thermal drive-in process 270 (e.g., drive-in temperature, time, ambient, pressure, etc.) can be configured to provide doped gate dielectric layer 264′ with a desired dipole dopant concentration in doped gate dielectric layer 264′. In some embodiments, concentrations of p-dipole dopant gradually decrease within gate dielectric layer 264′ from a top surface of gate dielectric layer 264′ to the interface 276.

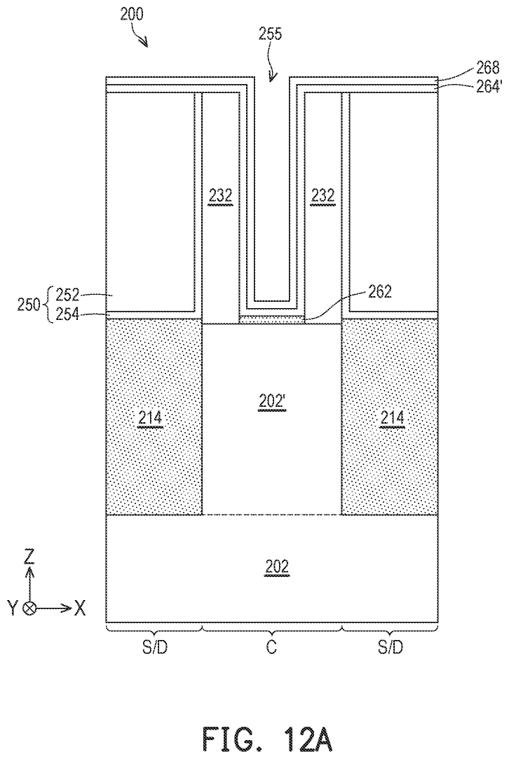

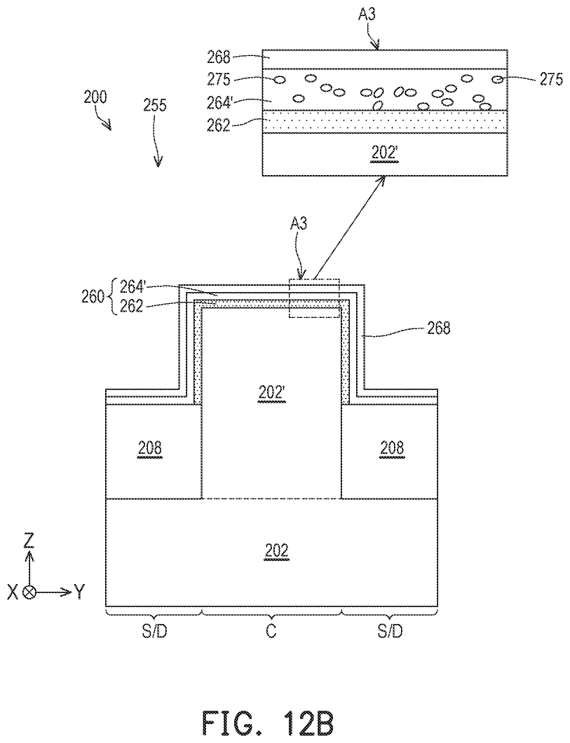

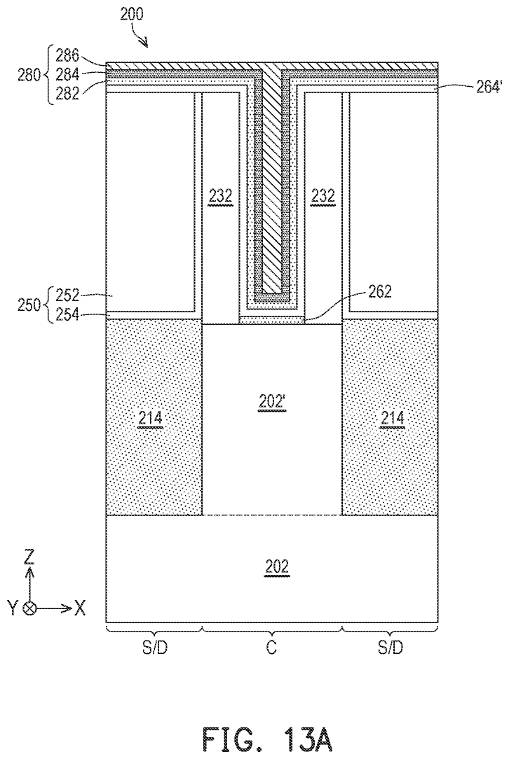

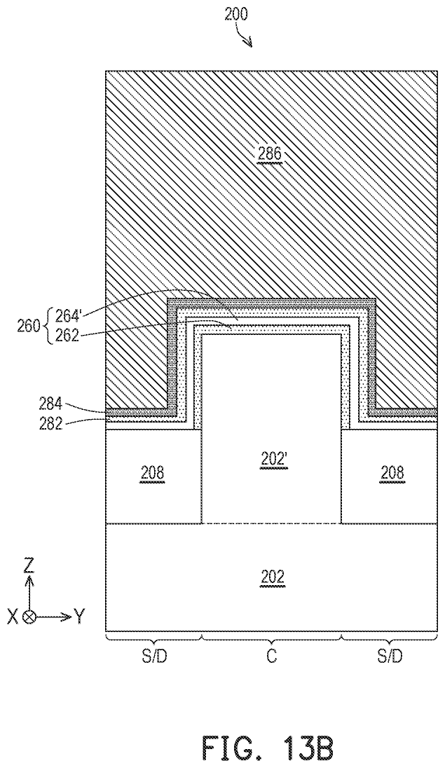

Referring to FIGS. 1 and 12A-12B, in some embodiments, method 100 at block 160 includes forming an additional gate dielectric layer 268 over the gate dielectric layer 264′. Block 160 is optional. It is understood that FIGS. 13A-14B show workpiece 200 without block 160. Additional gate dielectric layer 268 may include similar materials and be formed using similar methods as undoped gate dielectric layer 264. Additional gate dielectric layer 268 may have a substantially uniform thickness. After the forming of additional gate dielectric layer 268, p-dipole dopants 275 may be trapped within gate dielectric layer 264′. In other words, a majority (e.g., greater than 95%) of p-dipole dopants 275 diffused into gate dielectric layer 264 stay within gate dielectric layer 264 and do not diffuse into additional gate dielectric layer 268 or interfacial layer 262 in following processes.

Referring to FIGS. 1 and 13A-14B, at block 165 of method 100, gate electrode 280 is formed over gate dielectric layer 264′. Gate electrode 280 fills a remainder of gate opening 255, and gate electrode 280 includes at least one electrically conductive gate layer. The electrically conductive gate layer includes an electrically conductive material, such as Al, Cu, Ti, Ta, W, Mo, Co, TaN, NiSi, CoSi, TiN, WN, TiAl, TiAlN, TaCN, TaC, TaSiN, other electrically conductive material, or a combination thereof.

Referring to FIGS. 13A-13B, in some embodiments, forming gate electrode 280 can include depositing a work function layer 282 over gate dielectric layer 264′, depositing a barrier layer 284 over work function layer 282, and depositing a bulk (fill) layer 286 over barrier layer 284. Work function layer 282 partially fills gate opening 255, barrier layer 284 partially fills gate opening 255, and bulk layer 286 fills a remainder of gate opening 255. Work function layer 282 and barrier layer 284 have substantially uniform thicknesses. In some embodiments, each layer of gate electrode 280 (here, work function layer 282, barrier layer 284, and bulk layer 286) has a thickness of about 0.5 nm to about 5 nm. Work function layer 282, barrier layer 284, and bulk layer 286 can be formed by ALD, PVD, CVD, high density plasma CVD (HDPCVD), metal organic CVD (MOCVD), remote plasma CVD (RPCVD), plasma enhanced CVD (PECVD), low-pressure CVD (LPCVD), atomic layer CVD (ALCVD), atmospheric pressure CVD (APCVD), other suitable process, or a combination thereof.

Work function layer 282 is a conductive layer tuned to have a desired work function, such as an n-type work function or a p-type work function. For example, where transistor T1 is configured as an n-type transistor or a p-type transistor, work function layer 282 can include an n-type work function material or a p-type work function material, respectively. N-type work function materials include Ti, Al, Ag, Mn, Zr, TiAl, TiAlC, TaC, TaCN, TaSiN, TaAl, TaAlC, TiAlN, other n-type work function material, or combinations thereof. P-type work function materials include TiN, TaN, Ru, Mo, Al, WN, ZrSi₂, MoSi₂, TaSi₂, NiSi₂, WN, other p-type work function material, or combinations thereof. In some embodiments, work function layer 282 has a multilayer structure. In some embodiments, both p-type transistors and n-type transistors can be flexibly provided with multiple threshold voltages by incorporating p-dipole dopant (e.g., A1) into gate dielectric layer 264 using the disclosed dipole dopant source layer 266 even with a same work function material. This can obviate the need of patterning work function materials, making the disclosed dipole engineering process very suitable for nano-sized transistors, such as FinFETs and GAA transistors.

Bulk layer 286 includes a suitable conductive material, such as Al, W, Cu, Ti, Ta, TiN, TaN, polysilicon, other suitable metal(s) and/or alloys thereof, or a combination thereof. For example, bulk layer 286 is a tungsten layer formed by PVD or CVD. In some embodiments, barrier (blocking) layer 284 is optionally formed (e.g., by ALD) over work function layer 282 before forming bulk layer 286, such that barrier layer 284 is disposed between bulk layer 286 and work function layer 282. In some embodiments, barrier layer 284 includes a material that prevents or eliminates diffusion and/or reaction of constituents between adjacent layers and/or promotes adhesion between adjacent layers, such as between work function layer 282 and bulk layer 286. In some embodiments, barrier layer 284 includes metal and nitrogen, such as titanium nitride, tantalum nitride, tungsten nitride (e.g., W₂N), titanium silicon nitride (TiSiN), tantalum silicon nitride (TaSiN), other suitable metal nitride, or a combination thereof.

Referring to FIGS. 14A-14B, a planarization process is performed to remove excess gate materials, such as those disposed over dielectric layer 250. For example, a CMP process is performed that removes portions of bulk layer 286, barrier layer 284, work function layer 282, and gate dielectric layer 264′ disposed over dielectric layer 250. The CMP process is performed until a top surface of dielectric layer 250 is reached (exposed). In some embodiments, the CMP process is continued and reduces a thickness of dielectric layer 250, and correspondingly, a height of gate structure 220′. In the depicted embodiment, a top of gate structure 220′ is substantially planar with a top of dielectric layer 250 after the CMP process, and remainders of the gate materials, which fill gate opening 255, form the gate stack of gate structure 220′. As noted above, the gate stack includes gate dielectric 260 (e.g., interfacial layer 262 and gate dielectric layer 264′ (and, in some embodiments, gate dielectric layer 268)) and gate electrode 280 (e.g., bulk layer 286, barrier layer 284, and work function layer 282). Since gate dielectric layer 264′ is a high-k dielectric layer, the gate stack can be referred to as a high-k/metal gate. In some embodiments not depicted, processing can further include etching back gate electrode 280 and/or gate dielectric 260 (i.e., gate dielectric layer 264′ thereof) and forming a hard mask of the gate stack over the etched-back gate electrode 280 and/or gate dielectric 260.

In some embodiments, fabrication of transistor T1 can further include forming various contacts that can facilitate operation thereof. For example, one or more dielectric layers, similar to dielectric layer 250, can be formed over gate structure 220′ and dielectric layer 250. Contacts can then be formed in dielectric layer 250 and/or dielectric layers disposed over dielectric layer 250. For example, contacts are formed that are physically and/or electrically coupled, respectively, to the gate stack of gate structure 220′ (e.g., gate electrode 280 thereof) and at least one epitaxial source/drain 214 of transistor T1. For example, source/drain contacts are formed in dielectric layer 250, and source/drain contacts are disposed on epitaxial source/drains 214. Contacts include a conductive material, such as metal. Metals include aluminum, aluminum alloy (such as aluminum/silicon/copper alloy), copper, copper alloy, titanium, titanium nitride, tantalum, tantalum nitride, tungsten, polysilicon, metal silicide, other suitable metals, or a combination thereof. The metal silicide may include nickel silicide, cobalt silicide, tungsten silicide, tantalum silicide, titanium silicide, platinum silicide, erbium silicide, palladium silicide, or a combination thereof. In some embodiments, dielectric layers disposed over dielectric layer 250 and the contacts (for example, a gate contact and/or source/drain contacts extending through dielectric layer 250 and/or dielectric layers disposed thereover) are a portion of the MLI feature disposed over substrate 202.

In some embodiments, workpiece 200 includes a plurality of transistors (e.g., transistor T1), each of which includes a gate dielectric layer 264 in a gate region 255. The plurality of transistors may be tuned to have various Vt using method 100 described above in conjunction with dipole patterning processes.

For example, FIG. 15 is an exemplary diagram showing a dipole patterning process 300 that may be used in conjunction with blocks 130, 150, and 155 of method 100. The plurality of transistors may include gate regions 255 (e.g., 255-1, 255-2, . . . 255-n, 255-(n+1)). The dipole patterning process 300 may include n dipole loops. n is an integer greater than 1. Each dipole loop may include a patterning process and operations at block 130 as described above to form a dipole dopant source layer 266 in certain gate regions 255. The patterning process includes masking certain gate regions 255 while exposing other gate regions 255. FIG. 15 shows a simplified version of substrate 202, channels 202′ (e.g., 202′-1, 202′-2, . . . 202′-n, 202′-(n+1)) over substrate 202, interfacial layers 262 (e.g., 262-1, 262-2, . . . 262-n, 262-(n+1)) over respective channels 202′, and gate dielectric layers 264 (e.g., 264-1, 264-2, . . . 264-n, 264-(n+1)) over respective interfacial layers 262. As shown, the 1st loop DL1 of the n dipole loops provides dopants to drive into gate dielectric layer 264 in gate region 255-1 but not in gate regions 255-2 through 255-(n+1). In some examples (approach I), the 1st loop DL1 includes forming a mask (e.g., a hard mask) over gate regions 255-2 through 255-(n+1) while gate region 255-1 is exposed using any suitable processes (e.g., depositing, patterning using photolithography, etching), depositing a dipole dopant source layer over gate dielectric layer 264-1 in gate region 255-1 (e.g., as described for block 130) while the mask covers gate regions 255-2 through 255-(n+1), removing the mask from gate regions 255-2 through 255-(n+1) using any suitable processes, performing a thermal drive-in process to drive dopants from the dipole dopant source layer into gate dielectric layer 264-1 (e.g., as described for block 150), and removing the dipole dopant source layer from gate region 255-1 (e.g., as described for block 155). In some alternative examples (approach II), the 1st loop DL1 includes depositing a dipole dopant source layer over gate dielectric layers 264 in gate regions 255-1 through 255-(n+1) (e.g., as described for block 130), forming a mask over gate region 255-1 but leaving gate regions 255-2 through 255-(n+1) exposed, removing the dipole dopant source layer from gate regions 255-2 through 255-(n+1), removing the mask from gate region 255-1, performing a thermal drive-in process to drive dopants from the dipole dopant source layer into gate dielectric layer 264-1 in gate region 255-1 (e.g., as described for block 150), and removing the dipole dopant source layer in gate region 255-1 (e.g., as described for block 155).

Then, the 2nd loop DL2 of the n dipole loops provides dopants to drive into gate dielectric layers 264 in gate regions 255-1 and 255-2 but not in gate regions 255-3 through 255-(n+1). In some examples, the 2nd loop DL2 includes steps similar to those described above for approach I. In such examples, the mask is formed in gate regions 255-3 through 255-(n+1), the dipole dopant source layer is deposited over gate dielectric layers 264-1 and 264-2 in gate regions 255-1 and 255-2, and the thermal drive-in process drives dopants from the dipole dopant source layer into gate dielectric layers 264-1 and 264-2. In some other examples, the 2nd loop DL2 includes steps similar to those disclosed for approach II described above. In such examples, the mask is formed in gate regions 255-1 and 255-2 but leaving gate regions 255-3 through 255-(n+1) exposed, and the thermal drive-in process drives dopants from the dipole dopant source layer into gate dielectric layers 264-1 and 264-2. Then, the 3rd loop DL3 of the n dipole loops provides dopants to drive into gate dielectric layers 264 in gate regions 255-1 through 255-3 but not in gate regions 255-4 through 255-(n+1). The 3rd loop DL3 may include similar steps to those described above for approach I and approach II. For example, gate regions 255-4 through 255-(n+1) are masked when performing the 3rd loop DL3. By the end of the 3rd loop DL3, gate region 255-1 has undergone the dipole loop process 3 times, gate region 255-2 has undergone the dipole loop process 2 times, gate region 255-3 has undergone the dipole loop process 1 time, and gate regions 255-4 through 255-(n+1) has undergone the dipole loop process 0 times.

Note that additional dipole loops may be performed in cases that have additional number of gate regions. Each of the dipole loop (e.g., DL1, DL2, DL3) of the n dipole loops may increase atomic concentration of the dopants (e.g., A1) in corresponding gate dielectric layer(s) 264 by about 0% to about 5%. For example, the 1st loop DLI may drive the dopants into gate dielectric layer 264-1, thereby increasing atomic concentration of the dopants (e.g., A1) in gate dielectric layer 264-1 by about 0% to about 5%. For example, before the 1st loop DL1, atomic concentration of A1 in gate dielectric 264-1 may be 0%; and, after the 1st loop DL1, atomic concentration of A1 in gate dielectric layer 264-1 may increase to greater than 0% and less than or equal to about 5%. After dipole patterning process 300, gate electrode 280 is deposited over gate regions 255.

Note also that in the dipole patterning process 300, when using approach I for all the n dipole loops, after each n dipole loop, the number of gate regions 255 being masked is decreased until one gate region 255 is masked. This may be done by forming a mask in each dipole loop as described above for approach I. Alternatively, this may be done by removing portions of a same original hard mask from one end (e.g., right end) after each dipole loop. When using approach I for all the n dipole loops, performing the thermal drive-in process and removing the dipole dopant source layer (blocks 150 and 155) may be done in each n dipole loop. Alternatively, performing the thermal drive-in process and removing the dipole dopant source layer(s) may be done together after performing all or some of the n dipole loops, which drive different amounts of the dopants from one or more layers of the dipole dopant source layers into gate dielectric layers 264 in different gate regions and result in different dopant concentrations therein.

The resulting structure may include (n+1) of the structure reflected in the embodiment of FIGS. 14A and 14B, where gate dielectric layers 264′ of n of the structure have various p-dipole dopants concentration. Gate dielectric layer 264-(n+1) in gate region 255-(n+1) is not subjected to dipole engineering. Due to the number of loops performed, the p-dipole dopant concentration varies from gate regions 255-1 through 255-(n+1) (e.g., p-dipole dopant concentration may decrease from gate dielectric layer 264-1 through 264-(n+1)). For example, 3 dipole loops are performed resulting in 4 different Vt across gate regions 255-1 through 255-4. In any case, in the dipole patterning process 300 where n is the number of dipole loops, (n+1) Vts are resulted. In other words, each loop provides one more Vt option. For example, 1 loop results in 2 Vts, 2 loops result in 3 Vts, 3 loops result in 4 Vts, and so on. Each Vt could be an NFET Vt or a PFET Vt. In some embodiments, each Vt is a PFET Vt.

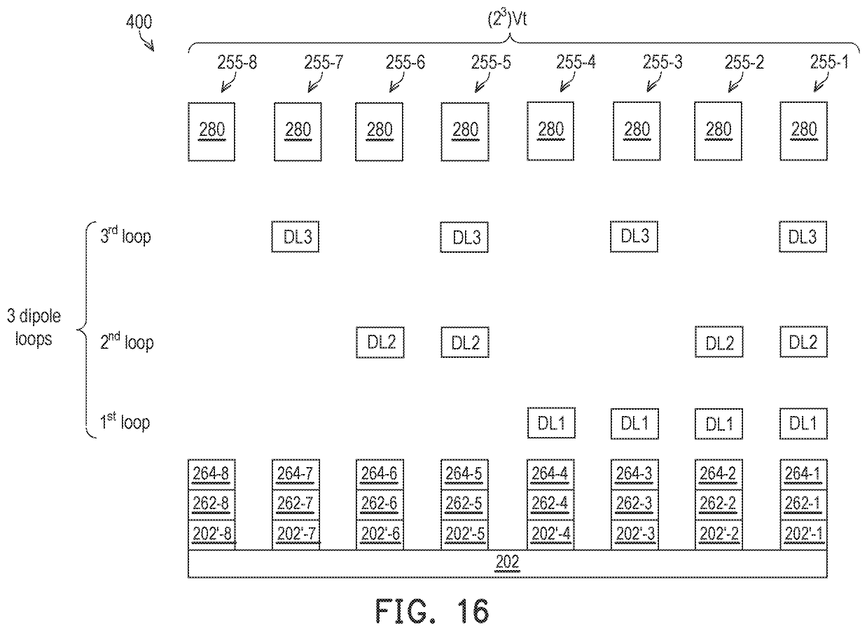

As another example, FIG. 16 is an exemplary diagram showing a dipole patterning process 400 that may be used in conjunction with blocks 130, 150, and 155 of method 100. The plurality of transistors may include gate regions 255 (e.g., 255-1, 255-2, . . . 255-8). In the illustrated example, the dipole patterning process 400 includes three dipole loops. Each dipole loop may include steps in approach I or approach II as described above, such as including a patterning process and operations at block 130 as described above. In some embodiments, the patterning process includes masking certain gate regions 255 while exposing other gate regions 255. FIG. 16 shows a simplified version of substrate 202, channels 202′ (e.g., 202′-1, 202′-2, . . . 202′-8) over substrate 202, interfacial layers 262 (e.g., 262-1, 262-2, . . . 262-8) over respective channels 202′, and gate dielectric layers 264 (e.g., 264-1, 264-2, . . . 264-8) over respective interfacial layers 262. After performing each of the 3 dipole loops, operations at blocks 150 and 155 as described above are performed. In some embodiments, after performing all of the 3 dipole loops, operations at blocks 150 and 155 as described above are performed. As shown, the 1st loop DLI is applied in gate regions 255-1 through 255-4 but not in gate regions 255-5 through 255-8. For example, gate regions 255-5 through 255-8 are masked when performing the 1st loop DL1. Then, the 2nd loop DL2 is applied in gate regions 255-1, 255-2, 255-5, and 255-6 but not in gate regions 255-3, 255-4, 255-7, and 255-8. For example, gate regions 255-3, 255-4, 255-7, and 255-8 are masked when performing the 2nd loop DL2. Then, the 3rd loop DL3 is applied in gate regions 255-1, 255-3, 255-5, and 255-7 but not in gate regions 255-2, 255-4, 255-6, and 255-8. For example, gate regions 255-2, 255-4, 255-6, and 255-8 are masked when performing the 3rd loop DL3. By the end of the 3rd loop DL3, gate region 255-1 has undergone the loops DL1, DL2, and DL3, gate region 255-2 has undergone the loops DL1 and DL2, gate region 255-3 has undergone the loops DL1 and DL3, gate region 255-4 has undergone the loop DL1, gate region 255-5 has undergone the loops DL2 and DL3, gate region 255-6 has undergone the loop DL2, gate region 255-7 has undergone the loop DL3, and gate region 255-8 has not undergone any DL loops. Although some of gate regions 255-1 to 255-8 experienced a same amount of dipole loops (e.g., gate regions 255-4 and 255-6 both experienced one dipole loop), all the gate regions 255 experienced a different combination of the dipole loops (e.g., no two gate regions experienced the same amount of the same dipole loop and thus no two gate regions have the same dipole dopant concentration and/or the same dipole dopant composition). For example, gate regions 255-4 and 255-7 both experienced one dipole loop, but one experienced DL1 and the other experienced DL3. After the second dipole patterning process 400, gate electrode 280 is deposited over gate regions 255.

By varying the amounts of p-dipole dopants driven into the gate dielectric layers in each applied loop (e.g., first loop drives more p-dipole dopants, second loop drives less p-dipole dopants, third loop drives even less p-dipole dopants), here, 3 dipole loops are performed resulting in 8 different Vt across gate regions 255-1 to 255-8.

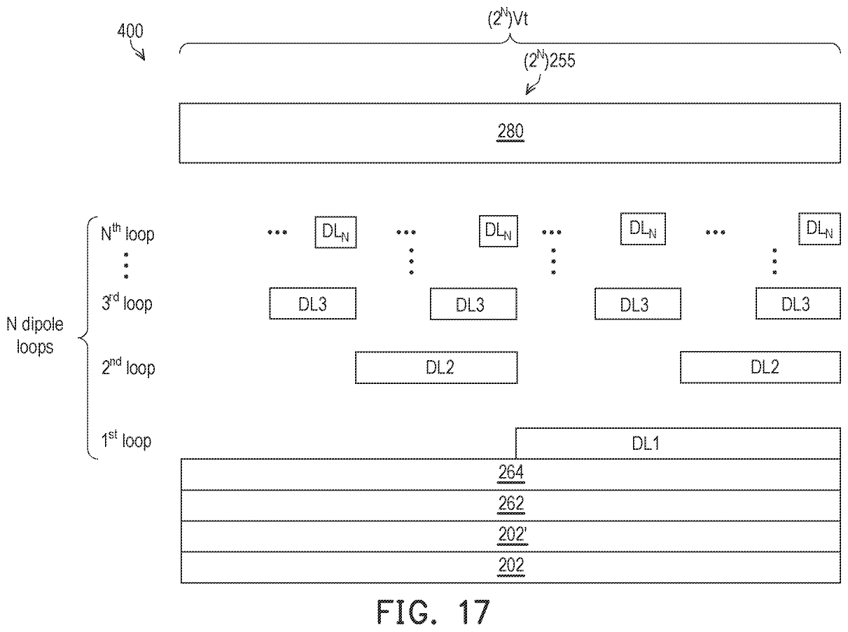

FIG. 17 is an exemplary diagram showing the dipole patterning process 400 where additional dipole loops may be performed in cases that have additional number of transistors including additional number of gate regions 255. FIG. 17 shows a more simplified version of substrate 202, channels 202′ over substrate 202, interfacial layers 262 over respective channels 202′, and gate dielectric layers 264 over interfacial layers 262. In any case, in the dipole patterning process 400 where N is the number of dipole loops, N loops may result in 2N different Vt. In other words, each loop doubles the Vt option (by patterning design). For example, 1 loop results in 2 Vts, 2 loops result in 4 Vts, 3 loops result in 8 Vts, and so on. After performing each of the N dipole loops, operations at blocks 150 and 155 as described above are performed. In some embodiments, after performing all of the N dipole loops, operations at blocks 150 and 155 as described above are performed. In some embodiments, each Vt is an NFET Vt or a PFET Vt. In embodiments, each Vt is a PFET Vt. As shown, integrating blocks 130, 150, and 155 of method 100 with the dipole patterning process 400 produces more threshold voltages per number of loops than integrating blocks 130, 150, and 155 of method 100 with the dipole patterning process 300.

The dipole patterning processes 300 and 400 target different gate regions 255 and can be achieved by any suitable lithography and patterning techniques. The patterning involved in the dipole patterning processes 300 and 400 may be achieved by any suitable methods. These combinations allow for p-dipole dopant variations in the gate dielectric layers 264 of workpiece 200.

As described above, transistor T1 is fabricated as a FinFET. In such embodiments, the channel 202′ is a portion of a semiconductor fin extending from substrate 202. In such embodiments, gate dielectric 260, dipole dopant source layer 266, and gate electrode 280 are formed over a top and sidewalls of a semiconductor fin.

While the examples described above relate to a formation of a FinFET, the principles described herein may be applied to other semiconductor structures such as a planar transistor, GAA devices, a stacked transistor, such as a complementary field effect transistor (CFET), etc.

In some other embodiments, the transistor is fabricated as a planar transistor. In such embodiments, the gate stack is disposed on one side of the channel (e.g., a top surface). For example, the channel is a portion of a semiconductor substrate, and the gate stack is disposed on a top surface of semiconductor substrate in the X-Z plane and the Y-Z plane. In such embodiments, gate dielectric 260, dipole dopant source layer 266, and gate electrode 280 are formed over a top of a channel region of a semiconductor substrate.

In some other embodiments, the transistor is fabricated as a GAA transistor (i.e., a transistor having a gate that surrounds at least one suspended channel (for example, nanowires, nanosheets, nanobars, etc.), where the at least one suspended channel extends between source/drains. To differentiate from the FinFET transistor described above, the GAA transistor is referred to as transistor T2 as part of alternative workpiece 500, such as in FIGS. 18A-19B. Compared with above description with respect to FIGS. 1-17, the following disclosure briefly discusses example differences of method 100 and dipole patterning processes 300 and 400 as depicted in FIGS. 1 and 15-17 for applying the present embodiments described above to transistor T2. Transistor T2 may be an n-type or a p-type transistor. In some embodiments, transistor T2 is a p-type transistor. It is noted that components common to workpiece 200 and workpiece 500 are referred to by the same notations in FIGS. 18A-19B as those in FIGS. 4-17.

Referring to FIGS. 4 and 18A-19B, workpiece 500 includes a transistor T2, which includes a channel (e.g., channel layers 506), mesa 202′, source/drains (e.g., epitaxial source/drains 214), and a gate (e.g., a gate stack that includes gate dielectric 260 and gate electrode 280). The gate engages the channel extending between the source/drains, and current can flow between the source/drains (e.g., between source and drain or vice versa) during operation. In the depicted embodiment, the gate is on a top and a bottom of the channel in the X-Z plane, and the gate surrounds the channel in the Y-Z plane (e.g., the gate stack is disposed on a top, a bottom, and sidewalls of channel layers 506). Transistor T2 may be an n-type or a p-type GAA transistor. In some embodiments, transistor T2 is a p-type GAA transistor.

Referring to FIGS. 1 and 18A-18B, fabricating workpiece 500 at block 105 may include depositing a semiconductor layer stack 510 (including first semiconductor layers 506 and second semiconductor layers not depicted) over substrate 202 and patterning semiconductor layer stack 510 and, optionally, substrate 202 to form fin-like structure 204 (or active region 204) extending from substrate 202. Fin-like structure 204 can include a patterned portion of semiconductor layer stack 510 (i.e., first semiconductor layers 506 and second semiconductor layers) and a patterned portion of substrate 202 (i.e., mesa 202′). A composition of first semiconductor layers 506 is different than a composition of second semiconductor layers to achieve etching selectivity and/or different oxidation rates during subsequent processing. First semiconductor layers 506 and second semiconductor layers include different materials, constituent atomic percentages, constituent weight percentages, thicknesses, or a combination thereof to achieve desired etching selectivity during an etching process, such as an etch process implemented to form suspended channel layers in channel region C. For example, first semiconductor layers 506 can be silicon layers, and second semiconductor layers can be silicon germanium layers. In some embodiments, first semiconductor layers 506 and second semiconductor layers are alternatingly epitaxially grown over substrate 202. In some embodiments, semiconductor layer stack 510 is patterned using a lithography process and an etching process. In some embodiments, fin-like structure 204 is formed by a fin fabrication process.

Workpiece 500 includes inner spacers 519 disposed under gate spacers 232 and along sidewalls of second semiconductor layers. Inner spacers 519 are disposed between and separate second semiconductor layers and epitaxial source/drains 214. Inner spacers 519 are further disposed between adjacent first semiconductor layers 506 and between bottommost first semiconductor layer 506 and mesa 202′. Inner spacers 519 include a dielectric material that includes silicon, oxygen, carbon, nitrogen, other suitable constituent, or a combination thereof, such as silicon oxide, silicon nitride, silicon oxynitride, silicon carbide, silicon oxycarbonitride, etc. In some embodiments, inner spacers 519 include a low-k dielectric material. In some embodiments, dopants (for example, p-type dopants, n-type dopants, or a combination thereof) are introduced into the dielectric material, and inner spacers 519 include doped dielectric material(s).

Referring to FIGS. 1 and 18A-18B, in such embodiments, after block 110, method 100 further includes block 115 where a channel release process is performed. For example, the second semiconductor layers of semiconductor layer stack 510 that are exposed by gate opening 255 are selectively removed to form air gaps 261 between first semiconductor layers 506 and between first semiconductor layers 506 and mesa 202′, thereby suspending first semiconductor layers 506 in channel region C. In the depicted embodiment, two suspended first semiconductor layers 506 are vertically stacked along the Z direction and provide two channels through which current can flow between epitaxial source/drains 214. Suspended first semiconductor layers 506 are thus referred to hereafter as channel layers 506. In embodiments where workpiece is formed of FinFETs, planar transistors, or other types of transistors, such as transistor T1 described above, the channel release process can be omitted from method 100.

Referring to FIGS. 1 and 19A-19B, at block 125, gate dielectric 260 is formed in gate opening 255 and over channel layers 506. Examples of differences from embodiments reflected in FIGS. 7A and 7B includes that interfacial layer 262 partially fills gate opening 255 and air gaps 261, such that interfacial layer 262 is between channel layers 506 and gate dielectric layer 264 and between mesa 202′ and gate dielectric layer 264. In the X-Z plane, interfacial layer 262 covers top surfaces of channel layers 506, bottom surfaces of channel layers 506, and a top surface of mesa 202′. In the Y-Z plane, interfacial layer 262 surrounds channel layers 506 and covers the top surface of mesa 202′. Gate dielectric layer 264 partially fills gate opening 255 and air gaps 261 and is formed on interfacial layer 262, gate spacers 232, inner spacers 519, isolation feature 208, and dielectric layer 250. In the Y-Z plane, gate dielectric layer 264 surrounds channel layers 506.

At block 130, dipole dopant source layer 266 is formed on gate dielectric layer 264 and partially fills gate opening 255 and air gaps 261. Examples of differences from embodiments reflected in FIGS. 8A and 8B includes that in the Y-Z plane, dipole dopant source layer 266 covers gate dielectric layer 264 and surrounds channel layers 506. Thus, dipole dopant source layer 266 may be disposed between channel layers 506 and between channel layers 506 and mesa 202′. In some embodiments, dipole dopant source layer 266 fills air gaps 261.

At block 160, examples of differences from embodiments reflected in FIGS. 12A and 12B includes that in the Y-Z plane, additional gate dielectric layer 268 covers gate dielectric layer 264′ and surrounds channel layers 506. Thus, additional gate dielectric layer 268 may be disposed between channel layers 506 and between channel layers 506 and mesa 202′. In some embodiments, additional gate dielectric layer 268 fills air gaps 261.

At block 165, examples of differences from embodiments reflected in FIGS. 14A and 14B includes that gate electrode 280 (e.g., work function layer 280, barrier layer 282, bulk layer 284) fill remainders of air gaps 261. Thus, gate electrode 280 may be disposed between channel layers 506 and between channel layers 506 and mesa 202′. In some embodiments, gate electrode 280 fills air gaps 261.

In some embodiments, workpiece 500 includes a plurality of GAA transistors (e.g., transistor T2) including a plurality of gate dielectric layers 264 in different gate regions 255, where gate stacks are designed to have different Vt for the plurality of GAA transistors. The dipole patterning processes 300 and 400 described above may also be applied to workpiece 500.

FIG. 20 illustrates another alternative workpiece 600 including a stacked transistor, such as a complementary field effect transistor (CFET), which can provide further density reduction for advanced IC technology nodes (particularly as IC technology nodes advance to 3 nm (N3) and below). It is noted that components common to workpieces 200, 500, and 600 are referred to by the same notations but with an ending “A” or “B” in FIG. 20 as those in FIGS. 4-19B.

In embodiments, workpiece 600 includes a device 612A, a device 612B, a substrate 202, and an insulation layer 616. Device 612B is vertically stacked over device 612A, insulation layer 616 is disposed between and separates device 612B and device 612A, and device 612A is disposed over substrate 202. In the depicted embodiment, device 612A and device 612B are stacked back-to-front. For example, a backside of device 612B is attached and/or bonded to a frontside of device 612A by insulation layer 616, which includes an insulation layer 616A and an insulation layer 616B. In some embodiments, insulation layer 616A is formed on the frontside of device 612A, insulation layer 616B is formed on the backside of device 612B, and insulation layer 616B is attached to insulation layer 616A. FIG. 20 has been simplified for the sake of clarity to better understand the inventive concepts of the present disclosure. Additional features can be added in workpiece 600, and some of the features described below can be replaced, modified, or eliminated in other embodiments of workpiece 600.

Device 612A and device 612B include at least one electrically functional device, such as a transistor TA and a transistor TB, respectively. Workpiece 600 thus includes a transistor stack having a top transistor (e.g., transistor TB) and a bottom transistor (e.g., transistor TA) separated and isolated by insulation layer 616. In some embodiments, transistor TA and transistor TB are transistors of an opposite conductivity type. For example, transistor TA is an n-type transistor, and transistor TB is a p-type transistor, or vice versa. In such embodiments, transistor TA and transistor TB form a CFET. In some embodiments, transistor TA and transistor TB are transistors of a same conductivity type. For example, transistor TA and transistor TB are both n-type transistors or p-type transistors.

In the depicted embodiment, transistors TA and TB are GAA transistors similar to transistor T2 described above. Devices 612A and 612B may each include various features and/or components, such as semiconductor layers 506A/506B, inner spacers 519A/519B, epitaxial source/drains 214A/214B, and gate structures 220A/220B, similar as those described herein. The gate stacks can further include hard mask layers 642A/642B, such as self-aligned cap (SAC) layers. Hard mask layers 642A/642B can include a dielectric material, such as silicon nitride. Devices 612A and 612B may further include source/drain contacts 651A/651B disposed on epitaxial source/drains 214A/214B.

Transistors (e.g., transistors TA and TB) of a stacked transistor structure, such as workpiece 600, can be fabricated separately, monolithically, or sequentially. When fabricated separately, a top transistor and a bottom transistor may be separately fabricated, and then, the top transistor is bonded/attached to the bottom transistor. When fabricated monolithically, a top transistor and a bottom transistor are fabricated from an initial device precursor. For example, a first set of semiconductor layers may be bonded/attached to a second set of semiconductor layers and then processed to form the top transistor and the bottom transistor, respectively. When fabricated sequentially, a first set of semiconductor layers may be processed to form a bottom transistor, and then, a second set of semiconductor layers is attached/bonded to the bottom transistor and processed to form a top transistor (i.e., the top transistor is fabricated on the bottom transistor).

Forming a first device of a stacked device structure, such as device 612A of workpiece 600 may be similar to the forming of the workpiece 500 as described above. Similar to gate dielectric 260, dipole engineering is performed on gate dielectrics 260A during the gate replacement process, such that gate dielectrics 260A also include p-dipole dopant Al.

Fabrication of device 612A can further include forming interconnects, such as gate contacts and/or source/drain contacts 651A, of device 612A. In some embodiments, forming source/drain contacts 651A includes forming source/drain contact openings in dielectric layer 250A that expose epitaxial source/drains 214A and forming at least one electrically conductive layer (e.g., metal) in the source/drain contact openings. A source/drain contact may include a metal silicide layer, a barrier/liner layer, and a bulk metal layer, where the barrier/liner layer is between the bulk metal layer and dielectric layer 250A (e.g., CESL 254A) and the bulk metal layer and the metal silicide layer. In some embodiments, one or more insulation layers may be formed in the source/drain contact openings and processed to form contact spacers, such as dielectric layers and/or air gaps, along sidewalls of electrically conductive portions of source/drain contacts 651A (e.g., barrier layer and/or bulk metal layer).

Then, device 612A of workpiece 600 and a second device of a stacked device structure, such as a precursor for fabricating device 612B may be attached and/or bonded. The precursor for fabricating device 612B may include a semiconductor layer stack 510B disposed over a substrate not depicted. In some embodiments, the substrate is a semiconductor substrate, such as a silicon substrate. In some embodiments, the substrate is a carrier substrate that includes silicon, soda-lime glass, fused silica, fused quartz, calcium fluoride, other suitable carrier substrate material, or a combination thereof.

In FIG. 20, device 612A is bonded and/or attached to the precursor of device 612B by insulation layer 616 (also referred to as a bonding layer). In some embodiments, device 612A is bonded to the precursor using dielectric-to-dielectric bonding. In some embodiments, insulation layer 616 is an oxide layer that attaches device 612A to the precursor for fabricating device 612B. In some embodiments, the dielectric-to-dielectric bonding process is an oxide-to-oxide bonding process that includes bonding an oxide layer formed on device 612A with an oxide layer formed on the precursor of device 612B. In some embodiments, a thickness of insulation (bonding) layer 616 is about 10 nm to about 100 μm.

After bonding, a thinning process and/or a de-bonding process may be performed to remove the substrate from the frontside of device 612B. For example, a planarization process, such as CMP, or an etching process can be performed to remove the substrate. Top second semiconductor layer of semiconductor layer stack 510B may function as a CMP stop layer and/or an etch stop layer when removing substrate. Thereafter, top second semiconductor layer may be removed from semiconductor layer stack 510B, for example, by an etching process. Removing top second semiconductor layer provides device 612B with a top first semiconductor layer 506B, which will provide a top channel of device 612B as described herein. Other methods and/or techniques for removing substrate and/or top second semiconductor layer are contemplated.

Thereafter, a second device of a stacked device structure, such as device 612B of workpiece 600 is formed similarly as the forming of the device 612A and workpiece 500 as described above.

Since device 612B is fabricated on device 612A, processes implemented to form transistor TB, such as the gate stack thereof, can negatively impact characteristics and/or reliability of device 612A. For example, high temperature processes can undesirably alter doping profiles of transistor TA, which can undesirably alter its threshold voltage, and/or degrade structural integrity of transistor TA, which can undesirably degrade its reliability. To minimize and/or eliminate such negative impacts, the gate stack and channel layers 506B of transistor TB are formed as described above, such that temperature or time of thermal drive-in process at block 150 may be reduced. For example, fabrication can include performing a disclosed dipole engineering process on the gate dielectric layer 264B to form doped gate dielectric layer 264B′.

The gate stacks of transistor TA may be configured the same or different than the gate stacks of transistor TB. In some embodiments, since transistor TA is configured as an n-type transistor and transistor TB is configured as a p-type transistor, or vice versa, gate dielectric 260A and gate dielectric 260B may include different dipole dopant conductivity types. For example, gate dielectric of the n-type transistor includes n-dipole dopant (e.g., lanthanum), and gate dielectric of the p-type transistor includes p-dipole dopant (e.g., aluminum) that is driven therein from disclosed dipole dopant source layer 266. Further, in such examples, gate electrode 280A and gate electrode 280B may include different work function materials. For example, gate electrode of the n-type transistor can include an n-type work function material, and gate electrode of the p-type transistor can include a p-type work function material. In some embodiments, gate dielectric 260A and gate dielectric 260B include different dipole dopant conductivity types, and gate electrode 280A and gate electrode 280B include the same electrically conductive materials (e.g., same work function materials).

In some embodiments, where transistor TA and transistor TB are both configured as same type transistors (e.g., p-type transistors), gate dielectric 260A and gate dielectric 260B include a same dipole dopant conductivity type (e.g., p-dipole dopant). Since transistor TA is a bottom transistor of workpiece 600 and is thus fabricated first, fabrication of transistor TA may not impact already fabricated devices and process temperatures, such as thermal drive-in temperatures and time, can be relaxed. For example, in some embodiments, gate dielectric 260A includes p-dipole dopant (e.g., A1) that can be driven therein from a first dipole dopant source layer excluding an Al layer at a first temperature for a first time period, while gate dielectric 260B includes p-dipole dopant from a second dipole dopant source layer that includes an A1 layer that is driven therein at a second temperature for a second time period. The second temperature may be lower than the first temperature, and/or the second time period may be less than the first time period. In some other embodiments, gate dielectric 260A and gate dielectric 260B include the same p-dipole dopant Al and the first and the second dipole dopant source layers may both include the Al layer disclosed herein. In such embodiments. thermal drive-in temperatures and/or time period to drive in the p-dipole dopant A1 may be reduced for both gate dielectric 260A and gate dielectric 260B.

In some embodiments, workpiece 600 includes stacked device structures including a plurality of transistors (e.g., transistors TA and TB). The plurality of transistors may include a plurality of gate dielectric layers in different gate regions, where gate stacks are designed to have different Vt for the plurality of transistors. The dipole patterning processes 300 and 400 described above may also be applied to workpiece 600.

Devices and/or structures described herein, such as workpiece 200, 500, and 600, etc. may be included in a microprocessor, a memory, other IC device, or a combination thereof. In some embodiments, structures described herein are a portion of an IC chip, a system on chip (SoC), or portion thereof, that includes various passive and active microelectronic devices, such as resistors, capacitors, inductors, diodes, p-type FETs (PFETs), n-type FETs (NFETs), metal-oxide semiconductor FETs (MOSFETs), stacked device structures, complementary metal-oxide semiconductor (CMOS) transistors, bipolar junction transistors (BJTs), laterally diffused MOS (LDMOS) transistors, high voltage transistors, high frequency transistors, other components, or a combination thereof.

The present disclosure provides gate stack (e.g., high-k/metal gate) fabrication methods that implement dipole engineering using a dipole dopant source layer including an Al layer and provides numerous advantages. Temperature and/or duration of thermal drive-in processes to a semiconductor structure may be reduced, which may reduce negative impacts on existing parts of the semiconductor structure. Disclosed methods also provide volume-free threshold voltage (Vt) tuning without varying metal gate structure dimensions from one device to another. Another example advantage is the flexibility to vary dopant concentration in different gate regions.

The gate stacks disclosed herein may be implemented in a variety of device types. For example, the gate stacks described herein are suitable for planar field-effect transistors (FETs), multigate transistors, such as FinFETs, GAA transistors, omega-gate (Ω-gate) devices, pi-gate (II-gate) devices, stacked device structures, or a combination thereof, as well as strained-semiconductor devices, silicon-on-insulator (SOI) devices, partially-depleted SOI devices, fully-depleted SOI devices, other devices, or a combination thereof. The present disclosure further contemplates that one of ordinary skill may recognize other semiconductor devices, such as capacitors, that can benefit from the material layer stacks and dipole engineering techniques described herein.

An exemplary method for forming a gate stack of a transistor includes forming a high-k dielectric layer, forming a p-dipole dopant source layer over the high-k dielectric layer, performing a thermal drive-in process that drives aluminum from the p-dipole dopant source layer into the high-k dielectric layer, and after removing the p-dipole dopant source layer, forming at least one electrically conductive gate layer over the high-k dielectric layer. The p-dipole dopant source layer includes an aluminum layer.

In some embodiments, the p-dipole dopant source layer further includes an aluminum oxide layer. In some embodiments, the forming of the p-dipole dopant source layer includes forming the aluminum layer over the high-k dielectric layer and forming the aluminum oxide layer over the aluminum layer. In some embodiments, the forming of the p-dipole dopant source layer includes forming the aluminum oxide layer over the high-k dielectric layer and forming the aluminum layer over the aluminum oxide layer. In some embodiments, the p-dipole dopant source layer further includes an aluminum nitride layer. In some embodiments, the p-dipole dopant source layer further includes an aluminum oxide layer and an aluminum nitride layer. In some embodiments, the forming of the p-dipole dopant source layer includes forming the aluminum layer using an aluminum chloride (AlCl₃) precursor and a trimethylaluminum (TMA) precursor. In some embodiments, the transistor includes a stack of channel layers, the forming of the high-k dielectric layer includes forming the high-k dielectric layer around each channel layer of the stack of channel layers. In some embodiments, the p-dipole dopant source layer is a first p-dipole dopant source layer and the thermal drive-in process is a first thermal drive-in process, and the method further includes forming a second p-dipole dopant source layer over the high-k dielectric layer, and performing a second thermal drive-in process that drives aluminum from the second p-dipole dopant source layer into the high-k dielectric layer. In some embodiments, the high-k dielectric layer is a first high-k dielectric layer, and the method further includes after the removing of the p-dipole dopant source layer and before the forming of the at least one electrically conductive gate layer over the high-k dielectric layer, forming a second high-k dielectric layer over the first high-k dielectric layer.

Another exemplary method includes forming a first interfacial layer over a first channel member and a second interfacial layer over a second channel member, forming a first gate dielectric over the first interfacial layer and a second gate dielectric over the second interfacial layer, performing a dipole engineering process including a dipole loop, and forming a gate electrode over the first gate dielectric and the second gate dielectric. The dipole loop includes performing an atomic layer deposition (ALD) process to form an aluminum layer over the first gate dielectric but not the second gate dielectric, performing a thermal drive-in process that drives aluminum from the aluminum layer into the first gate dielectric, thereby increasing an aluminum concentration in the first gate dielectric by less than about 5%, and removing the aluminum layer.

In some embodiments, a cycle of the ALD process includes flowing a first deposition gas into a process chamber, performing a first purging process, flowing a second deposition gas into the process chamber, and performing a second purging process. The first deposition gas includes aluminum chloride (AlCl3), the second deposition gas includes trimethylaluminum (TMA). The method includes repeating the cycle of the ALD process until the aluminum layer has a target thickness. In some embodiments, the ALD process is a first ALD process, and the dipole loop further includes performing a second ALD process to form an aluminum oxide layer over the first gate dielectric, and the performing of the thermal drive-in process further drives aluminum from the aluminum oxide layer into the first gate dielectric. In some embodiments, the ALD process is a first ALD process, and the dipole loop further includes performing a second ALD process to form an aluminum nitride layer over the first gate dielectric, and the performing of the thermal drive-in process further drives aluminum from the aluminum nitride layer into the first gate dielectric. In some embodiments, the ALD process is a first ALD process, and the dipole loop further includes performing a second ALD process to form an aluminum oxide layer over the first gate dielectric, performing a third ALD process to form an aluminum nitride layer over the first gate dielectric, and the performing of the thermal drive-in process further drives aluminum from the aluminum oxide layer and the aluminum nitride layer into the first gate dielectric. In some embodiments, the dipole loop is a first dipole loop, the aluminum layer is a first aluminum layer, the ALD process is a first ALD process, and the thermal drive-in process is a first thermal drive-in process, and the dipole engineering process further includes a second dipole loop. The second dipole loop includes performing a second ALD process to form a second aluminum layer over the second gate dielectric, performing a second thermal drive-in process that drives aluminum from the second aluminum layer into the second gate dielectric, thereby increasing an aluminum concentration in the second gate dielectric by less than about 5%, and removing the second aluminum layer. In some embodiments, the performing of the second ALD process further forms the second aluminum layer over the first gate dielectric, and the performing of the second thermal drive-in process further drives aluminum from the second aluminum layer into the first gate dielectric, thereby increasing the aluminum concentration in the first gate dielectric by less than about 5%.

An exemplary method includes forming a device including a first gate region and a second gate region. The first gate region includes a first channel member, a first gate dielectric over the first channel member, and a first gate electrode layer over the first gate dielectric. The second gate region includes a second channel member, a second gate dielectric over the second channel member, and a second gate electrode layer over the second gate dielectric. The first gate dielectric and the second gate dielectric include different concentrations of aluminum. The forming of the device includes forming an aluminum layer over the first gate dielectric but not the second gate dielectric, performing an annealing process that drives aluminum from the aluminum layer into the first gate dielectric, thereby increasing an atomic concentration of aluminum in the first gate dielectric by less than about 5%, removing the aluminum layer, and forming the first gate electrode layer over the first gate dielectric and the second gate electrode layer over the second gate dielectric.

In some embodiments, the aluminum layer is a first aluminum layer, the annealing process is a first annealing process. The forming of the device further includes forming a second aluminum layer over the first gate dielectric and the second gate dielectric, performing a second annealing process that drives aluminum from the second aluminum layer into the first gate dielectric and the second gate dielectric, thereby increasing an atomic concentration of aluminum in the second gate dielectric and the atomic concentration of aluminum in the first gate dielectric by less than about 5%, and removing the second aluminum layer. In some embodiments, the device further includes a third gate region. The third gate region includes a third channel member, a third gate dielectric over the third channel member, and a third gate electrode layer over the third gate dielectric. The first gate dielectric, the second gate dielectric, and the third gate dielectric include different concentrations of aluminum. The forming of the device further includes forming a third aluminum layer over the first gate dielectric, the second gate dielectric, and the third gate dielectric, performing a third annealing process that drives aluminum from the third aluminum layer into the first gate dielectric, the second gate dielectric, and the third gate dielectric, and removing the third aluminum layer.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method for forming a gate stack of a transistor, comprising:
forming a high-k dielectric layer;
forming a p-dipole dopant source layer over the high-k dielectric layer, wherein the p-dipole dopant source layer includes an aluminum layer;
performing a thermal drive-in process that drives aluminum from the p-dipole dopant source layer into the high-k dielectric layer; and
after removing the p-dipole dopant source layer, forming at least one electrically conductive gate layer over the high-k dielectric layer.

2. The method of claim 1, wherein the p-dipole dopant source layer further includes an aluminum oxide layer.

3. The method of claim 2, wherein the forming of the p-dipole dopant source layer includes:
forming the aluminum layer over the high-k dielectric layer; and
forming the aluminum oxide layer over the aluminum layer.

4. The method of claim 2, wherein the forming of the p-dipole dopant source layer includes:
forming the aluminum oxide layer over the high-k dielectric layer; and
forming the aluminum layer over the aluminum oxide layer.

5. The method of claim 1, wherein the p-dipole dopant source layer further includes an aluminum nitride layer.

6. The method of claim 1, wherein the p-dipole dopant source layer further includes an aluminum oxide layer and an aluminum nitride layer.

7. The method of claim 1, wherein the forming of the p-dipole dopant source layer includes forming the aluminum layer using an aluminum chloride (AlCl₃) precursor and a trimethylaluminum (TMA) precursor.

8. The method of claim 1, wherein the transistor includes a stack of channel layers,
wherein the forming of the high-k dielectric layer includes forming the high-k dielectric layer around each channel layer of the stack of channel layers.

9. The method of claim 1, wherein:
the p-dipole dopant source layer is a first p-dipole dopant source layer and the thermal drive-in process is a first thermal drive-in process; and
the method further comprises:
forming a second p-dipole dopant source layer over the high-k dielectric layer, and
performing a second thermal drive-in process that drives aluminum from the second p-dipole dopant source layer into the high-k dielectric layer.

10. The method of claim 1, wherein:
the high-k dielectric layer is a first high-k dielectric layer; and
the method further comprises after the removing of the p-dipole dopant source layer and before the forming of the at least one electrically conductive gate layer over the high-k dielectric layer, forming a second high-k dielectric layer over the first high-k dielectric layer.

11. A method comprising:
forming a first interfacial layer over a first channel member and a second interfacial layer over a second channel member;
forming a first gate dielectric over the first interfacial layer and a second gate dielectric over the second interfacial layer;
performing a dipole engineering process including a dipole loop, wherein the dipole loop includes:
performing an atomic layer deposition (ALD) process to form an aluminum layer over the first gate dielectric but not the second gate dielectric,
performing a thermal drive-in process that drives aluminum from the aluminum layer into the first gate dielectric, thereby increasing an aluminum concentration in the first gate dielectric by less than about 5%, and
removing the aluminum layer; and
forming a gate electrode over the first gate dielectric and the second gate dielectric.

12. The method of claim 11, wherein:
a cycle of the ALD process includes:
flowing a first deposition gas into a process chamber, wherein the first deposition gas includes aluminum chloride (AlCl3),
performing a first purging process,
flowing a second deposition gas into the process chamber, wherein the second deposition gas includes trimethylaluminum (TMA), and
performing a second purging process; and
the method includes repeating the cycle of the ALD process until the aluminum layer has a target thickness.

13. The method of claim 11, wherein:
the ALD process is a first ALD process; and
the dipole loop further includes:
performing a second ALD process to form an aluminum oxide layer over the first gate dielectric, and
wherein the performing of the thermal drive-in process further drives aluminum from the aluminum oxide layer into the first gate dielectric.

14. The method of claim 11, wherein:
the ALD process is a first ALD process; and
the dipole loop further includes:
performing a second ALD process to form an aluminum nitride layer over the first gate dielectric, and
wherein the performing of the thermal drive-in process further drives aluminum from the aluminum nitride layer into the first gate dielectric.

15. The method of claim 11, wherein:
the ALD process is a first ALD process; and
the dipole loop further includes:
performing a second ALD process to form an aluminum oxide layer over the first gate dielectric,
performing a third ALD process to form an aluminum nitride layer over the first gate dielectric, and
wherein the performing of the thermal drive-in process further drives aluminum from the aluminum oxide layer and the aluminum nitride layer into the first gate dielectric.

16. The method of claim 11, wherein:
the dipole loop is a first dipole loop, the aluminum layer is a first aluminum layer, the ALD process is a first ALD process, and the thermal drive-in process is a first thermal drive-in process; and
the dipole engineering process further includes a second dipole loop including:
performing a second ALD process to form a second aluminum layer over the second gate dielectric,
performing a second thermal drive-in process that drives aluminum from the second aluminum layer into the second gate dielectric, thereby increasing an aluminum concentration in the second gate dielectric by less than about 5%, and
removing the second aluminum layer.

17. The method of claim 16, wherein:
the performing of the second ALD process further forms the second aluminum layer over the first gate dielectric; and
the performing of the second thermal drive-in process further drives aluminum from the second aluminum layer into the first gate dielectric, thereby increasing the aluminum concentration in the first gate dielectric by less than about 5%.

18. A method, comprising:
forming a device including a first gate region and a second gate region,
wherein the first gate region includes a first channel member, a first gate dielectric over the first channel member, and a first gate electrode layer over the first gate dielectric,
wherein the second gate region includes a second channel member, a second gate dielectric over the second channel member, and a second gate electrode layer over the second gate dielectric,
wherein the first gate dielectric and the second gate dielectric include different concentrations of aluminum, and
wherein the forming of the device includes:
forming an aluminum layer over the first gate dielectric but not the second gate dielectric,
performing an annealing process that drives aluminum from the aluminum layer into the first gate dielectric, thereby increasing an atomic concentration of aluminum in the first gate dielectric by less than about 5%,
removing the aluminum layer, and
forming the first gate electrode layer over the first gate dielectric and the second gate electrode layer over the second gate dielectric.

19. The method of claim 18, wherein the aluminum layer is a first aluminum layer, the annealing process is a first annealing process; and
the forming of the device further includes:
forming a second aluminum layer over the first gate dielectric and the second gate dielectric,
performing a second annealing process that drives aluminum from the second aluminum layer into the first gate dielectric and the second gate dielectric, thereby increasing an atomic concentration of aluminum in the second gate dielectric and the atomic concentration of aluminum in the first gate dielectric by less than about 5%, and
removing the second aluminum layer.

20. The method of claim 19, wherein the device further includes a third gate region;
wherein the third gate region includes a third channel member, a third gate dielectric over the third channel member, and a third gate electrode layer over the third gate dielectric;
wherein the first gate dielectric, the second gate dielectric, and the third gate dielectric include different concentrations of aluminum; and
the forming of the device further includes:
forming a third aluminum layer over the first gate dielectric, the second gate dielectric, and the third gate dielectric,
performing a third annealing process that drives aluminum from the third aluminum layer into the first gate dielectric, the second gate dielectric, and the third gate dielectric, and
removing the third aluminum layer.
